(19) United States
(12) Patent Application Publication
(10) Pub. No.: US 2024/0429815 A1
(43) Pub. Date: Dec. 26, 2024

(54) SWITCHED CAPACITOR VOLTAGE CONVERTER

(71) Applicants: Huanhuan Zhang, Ashland, MA (US); Keng CHEN, Acton, MA (US); Arvind Raghavan, Lexington, MA (US); Christopher Schaef, Hillsboro, OR (US); Tamir Salus, Zichron Yaakov (IL); Sivaraman Masilamani, Northborough, MA (US)

(72) Inventors: Huanhuan Zhang, Ashland, MA (US); Keng CHEN, Acton, MA (US); Arvind Raghavan, Lexington, MA (US); Christopher Schaef, Hillsboro, OR (US); Tamir Salus, Zichron Yaakov (IL); Sivaraman Masilamani, Northborough, MA (US)

(21) Appl. No.: 18/214,014

(22) Filed: Jun. 26, 2023

(51) Int. Cl. H02M 3/07; H02M 1/00; H03K 3/037

(52) U.S. Cl. CPC H02M 3/07; H02M 1/0048; H03K 3/037

(57) ABSTRACT

Some embodiments include a voltage regulator including a clock node to receive an input clock signal, and first and second power switching blocks coupled to the clock node. The first power switching block includes a first clock generator and first switched capacitor circuitry. The first clock generator includes clock output nodes to provide first clock signals based on the input clock signal. The first switched capacitor circuitry includes input nodes to receive first control signals generated based on the first clock signals. The second power switching block includes a second clock generator and second switched capacitor circuitry. The second clock generator includes clock output nodes to provide second clock signals based on the input clock signal. The second switched capacitor circuitry includes input nodes to receive second control signals generated based on the second clock signals.

### TECHNICAL FIELD

Embodiments described herein pertain to switched capacitor voltage converters. Some embodiments relate to clock signal generators associated with switched capacitor voltage converters.

### BACKGROUND

Many electronic devices or systems, such as computers, tablets, and cellular phones, have voltage regulators to maintain voltages used by components in the device or system at proper values. Switched capacitor converter is one type of such voltage regulator. Some conventional switched capacitor converters may include many blocks of switched capacitor circuitry (switched capacitor blocks) that include capacitors and switching circuits (e.g., driver and transistor circuits) formed on a semiconductor die (e.g., a silicon die). In a conventional switched capacitor converter, current density is linearly proportional to clock signals used to control the switching of switching circuits in the switched capacitor converter. The switched capacitor converter normally has a main clock generator to generate clock signals and propagate the clock signals to the switched capacitor blocks. To achieve a relatively high current density, the frequency of such clock signals is often chosen to be relatively high (e.g., in the gigahertz (GHz) range). However, at such a high frequency, the main clock generator may consume a relatively large amount of power to generate and propagate clock signals to the switched capacitor blocks in the switched capacitor converter. The power consumption would be even larger if the switched capacitor blocks occupy a large (e.g., in millimeter range) linear dimension (e.g., length) of the area in the switched capacitor converter. Another drawback in such switched capacitor converter involves offsets (sometimes called deadtime) in the clock signals used to control switching circuits of the switched capacitor converter. In switched capacitor converters, deadtime in the clock signals is used to improve efficiency of the switched capacitor converter. A conventional switched capacitor converter that has many switched capacitor blocks may generate such deadtime with a large enough value (e.g., large deadtime guard band) and to allow proper operation of the switched capacitor converter under variations in factors such as process, voltage, and temperature (PVT) conditions. However, a large deadtime can restrict current density of the switched capacitor converter. Moreover, high-power consumption, large deadtime, or both can limit scalability of conventional switched capacitor converters.

### BRIEF DESCRIPTION OF THE DRAWINGS

FIG. 1 shows an apparatus including a voltage regulator, according to some embodiments described herein.

FIG. 2 shows a portion of a voltage regulating module of the voltage regulator of FIG. 1, according to some embodiments described herein.

FIG. 3A and FIG. 3B show timing relationships among some clock signals in the voltage regulating module of FIG. 2, according to some embodiments described herein.

FIG. 4A shows switched capacitor circuitry of a respective power switching block of FIG. 1, according to some embodiments described herein.

FIG. 4B and FIG. 4C show two circuit structures of a circuit of the switched capacitor circuitry of FIG. 4A, according to some embodiments described herein.

FIG. 5A shows a clock generator of a respective power switching block of FIG. 1, according to some embodiments described herein.

FIG. 5B is a timing diagram showing relative voltage levels associated with detection gate voltage crossing for generating deadtime in a clock signal generated by the clock generator of FIG. 5A, according to some embodiments described herein.

FIG. 6A and FIG. 6B show comparators of the clock generator of FIG. 5A, according to some embodiments described herein.

FIG. 7 shows a clock generator that can be variation of the clock generator of FIG. 5A, according to some embodiments described herein.

FIG. 8 shows another clock generator that can be variation of the clock generator of FIG. 5A, according to some embodiments described herein.

FIG. 9 shows an apparatus in the form of a system including the voltage regulator of FIG. 1, according to some embodiments described herein.

### DETAILED DESCRIPTION

The techniques described herein involve a voltage regulator that includes power switching blocks formed in the same semiconductor die. The power switching blocks can be located (e.g., formed) side-by-side among each other. Each of the power switching blocks includes switched capacitor circuitry and a clock generator located in the same power switching block with the switched capacitor circuitry. The clock generators of the power switching blocks receive the same input clock signal from a clock path (e.g., a single conductive line) that extends in an area adjacent the power switching blocks. The clock generator in the power switching block receives a clock signal (e.g., single clock signal) from the clock path and generates (locally generates) multiple clock signals. The clock signals locally generated by a clock generator of a power switching block are provided to the switched capacitor circuitry of the same power switching block. Clock signals can provide a time-interleaved clocking scheme for use in the power switching blocks. The time-interleaved clocking scheme allows switching circuits of different portions (e.g., different groups of the power switching blocks) to be controlled based on the clock signals generated by the clock generators of the switching blocks.

The described clock generator also includes circuits to generate deadtime associated with the clock signals. The deadtime can prevent switching circuits in some portions of the power switching block from concurrently (e.g., simultaneously) turn on during part of the operation of the power switching block. This allows the voltage regulator to maintain proper operation and provide improved efficiency. The clock generator in each power switching block includes circuits that are replicas (e.g., copies) of switching circuits in the power switching blocks. The replicas allow the deadtime to be adaptive to behaviors (e.g., turning off behaviors) of the switching circuits under different conditions (e.g., PVT) of switching circuits.

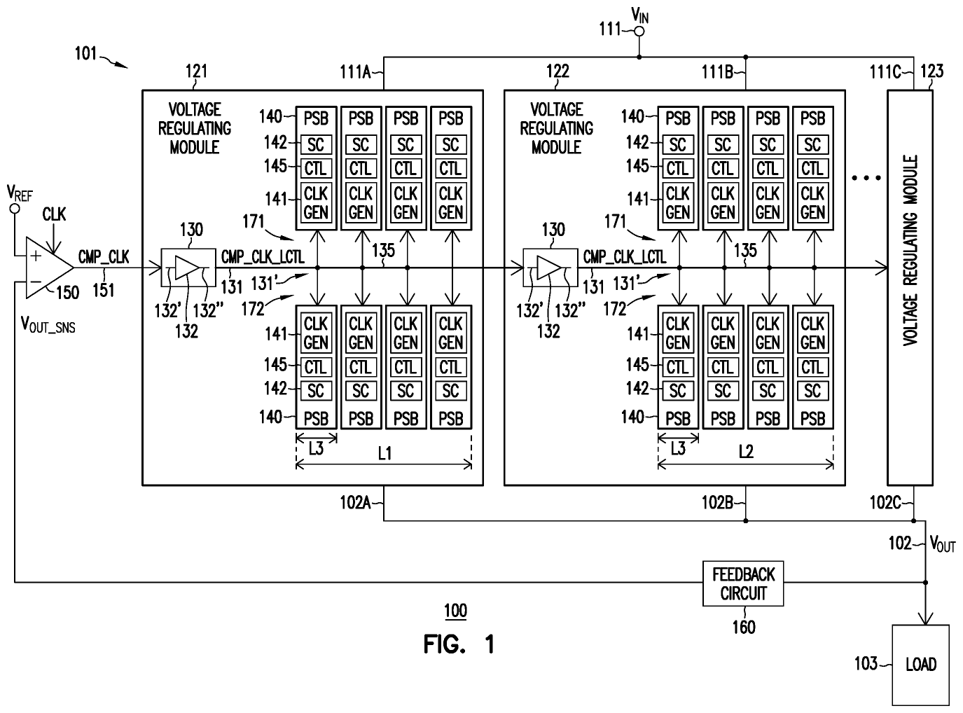

Improvements and benefits of the described techniques in comparison with some conventional techniques include lower power consumption, higher current density, and more flexibility in scalability. These and other improvements and benefits of the described techniques are discussed in more detail below with reference to FIG. 1 through FIG. 9.

FIG. 1 shows an apparatus 100 including a voltage regulator 101, according to some embodiments described herein. Apparatus 100 can include or be included in an electronic device or system, such as a computer (e.g., desktop, laptop, or notebook), a tablet, a cellular phone, a system on chip (SoC), a system in a package (SiP), or other electronic devices or systems. Voltage regulator 101 can operate to control (e.g., regulate) the value of a voltage V_{OUT} (e.g., regulated output voltage) at a node (e.g., voltage output node) 102. Voltage V_{OUT} can be provided (e.g., as a supply voltage) to other components, such as a load 103, of apparatus 100. Examples of load 103 include a processor, such as a central processing unit (CPU) of a CPU chip or a CPU package, a graphics processing unit (GPU) of a GPU chip or a GPU package, a memory device, and other electronic components of apparatus 100.

Voltage regulator 101 can be included in an integrated circuit (IC) die (e.g., an IC chip, such as a semiconductor chip). The IC die can include a semiconductor die (e.g., silicon-based die). In an example, voltage regulator 101 and load 103 can be included in separate IC dies (e.g., separate IC chips). In another example, voltage regulator 101 and load 103 can be included in the same IC die (e.g., same IC chip). In another example, voltage regulator 101 and load 103 can be part of an SoC. In another example, voltage regulator 101 and load 103 can be part of an SiP.

As shown in FIG. 1, voltage regulator 101 can include a node (e.g., voltage input node) 111 to receive a voltage (e.g., input voltage) V_{IN}, which can be a supply voltage provided by a power source (e.g., a battery). Voltage regulator 101 can generate voltage V_{OUT} from voltage V_{IN}. The value of voltage V_{OUT} can be based on the value of voltage V_{IN}. In an example, value of voltage V_{OUT} can be less than the value of voltage V_{IN}. In another example, value of voltage V_{OUT} can be greater than the value of voltage V_{IN}.

Voltage regulator 101 can include voltage regulating modules 121, 122, and 123. Voltage regulating modules 121, 122, and 123 can include respective nodes (e.g., voltage input nodes) 111A, 111B, and 111C coupled to node 111, and respective nodes (e.g., voltage output nodes) 102A, 102B, and 102C coupled to node 102. Voltage regulating modules 121, 122, and 123 can operate to provide (e.g., transfer) charge from respective nodes (e.g., voltage input nodes) 111A, 111B, and 111C (associated with voltage V_{IN}) to respective nodes 102A, 102B, and 102C (associated with voltage V_{OUT}). Voltage regulating modules 121, 122, and 123 can include similar (or the same) circuit elements. FIG. 1 shows voltage regulator 101 including three voltage regulating modules 121, 122, and 123. However, the number of voltage regulating modules can be different from three. For simplicity, descriptions of similar or the same circuit elements are not repeated in this description.

As shown in FIG. 1, each of voltage regulating modules 121 and 122 can include a respective clock path 131′, which includes a conductive line 135, to propagate (distribute) a clock signal (e.g., input clock signal) CMP_CLK_LCTL. Conductive line 135 can be formed on or formed in a semiconductor die where voltage regulator 101 is located. Conductive line 135 can include conductively doped polysilicon, metal, or other conductive materials. As shown in FIG. 1, clock path 131′ in voltage regulating module 121 can have a length that includes a length segment L1. Length segment L1 can be part of the length of conductive line 135. Length segment L1 can measured in meter units (e.g., in micrometers). Each of power switching blocks 140 can have footprint (e.g., layout) with a dimension (e.g., a length measured from left to right of FIG. 1) L3 parallel clock path 131′. Dimension L3 can be approximately 250 micron (250 um). Thus, length segment L1 can be approximately equal the total lengths of the number (e.g., four) of power switching blocks 140 in voltage regulating module 121.

Similarly, clock path 131′ in voltage regulating module 122 can have a length that includes a length segment L2 (e.g., measured in micrometers). In some structures of voltage regulator 101, each of length segments L1 and L2 can be approximately one millimeter (1 mm). In some structure of voltage regulator 101 examples, each of length segments L1 and L2 can be at least 1 mm (greater than 1 mm). Each of power switching blocks 140 in voltage regulating module 122 can have a dimension L3 parallel to clock path 131′ of voltage regulating module 122. Length segment L2 can be approximately equal the total lengths (e.g., measured from left to right) of the number (e.g., four) of power switching blocks 140 in voltage regulating module 122.

As shown in FIG. 1, each of voltage regulating modules 121 and 122 can include a clock controller (e.g., local clock controller) 130 to provide a clock signal (e.g., input clock signal) CMP_CLK_LCTL in a respective voltage regulating module 121 or 122. Clock controller 130 can include circuit elements (e.g., buffer circuitry 132) and can operate such that clock signal CMP_CLK_LCTL at its output node can be a buffered version of a clock signal received at its input node and have the same frequency as the clock signal received at its input node. For example, in voltage regulating module 121, buffer circuitry 132 can include an input node 132′ coupled to the output node (node 151) of a comparator 150 to receive a clock signal CMP_CLK from a comparator 150 and an output node 132″ provide clock signal CMP_CLK_LCTL, which can be a buffered version of clock signal CMP_CLK.

In voltage regulating module 122, buffer circuitry 132 can include an input node 132′ coupled to conductive line 135 of voltage regulating module 121 (e.g., coupled to output 132″ of buffer circuitry 132 of voltage regulating module 121) to receive clock signal CMP_CLK_LCTL from buffer circuitry 132 of voltage regulating module 122. Buffer circuitry 132 of voltage regulating module 122 can also include output node 132″ coupled to conductive line 135 of voltage regulating module 122 to provide a clock signal CMP_CLK_LCTL, which can be a buffered version of clock signal CMP_CLK_LCTL from voltage regulating module 121.

The frequency of signal CMP_CLK_LCTL in voltage regulating modules 121 and 122 can be based on (e.g., similar to or the same as) the frequency of clock signal CMP_CLK. The frequency of signal CMP_CLK_LCTL in voltage regulating module 121 and 122 can be based on (e.g., similar to or the same as) the frequency of signal CMP_CLK_LCTL in voltage regulating module 121.

Thus, as shown in FIG. 1, clock controller 130 of voltage regulating modules 121 can include an input node coupled to node (output node) 151 of comparator 150 and an output node coupled to node 131. In voltage regulating modules 121, node 131 can be part of clock path 131′ of voltage regulating module 121. Clock controller 130 of voltage regulating module 122 can include an input node coupled to node 131 of voltage regulating module 122, and an output node coupled to node 131 of voltage regulating module 122. In voltage regulating modules 122, node 131 can be part of clock path 131′ of voltage regulating modules 122. Node 131 in each of voltage regulating modules 121 can be called a clock node to provide a clock signal (instead of a data signal) such as clock signal CMP_CLK_LCTL in the respective voltage regulating module.

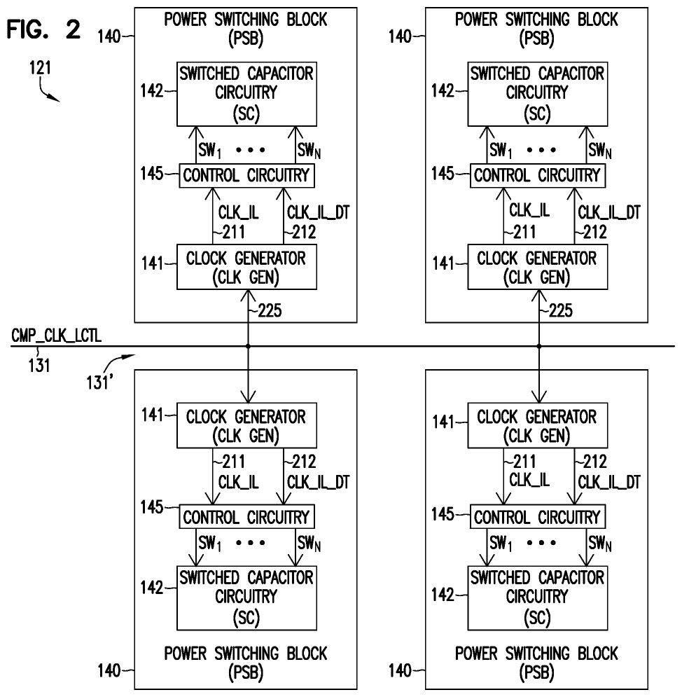

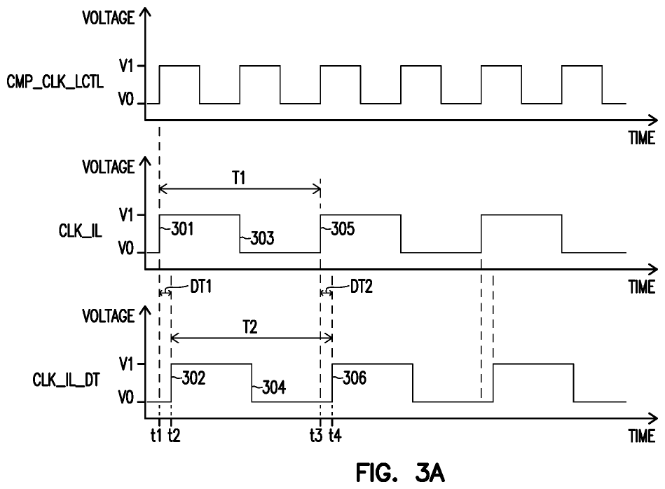

As shown in FIG. 1, each power switching block 140 can include a clock generator 141, switched capacitor circuitry 142, and control circuitry (e.g., logic circuitry) 145. In each power switching block 140, clock generator 141, switched capacitor circuitry 142, and control circuitry 145 are located (e.g., locally located) in the same power switching block 140. Each of the clock generators 141 can be coupled to node 131 through conductive line 135 of clock path 131′ in a respective voltage regulating module. Switched capacitor circuitry 142 can include capacitors and switching circuits (e.g., drivers and transistors, not shown in FIG. 1) that can form a network of capacitors and switching circuits to perform functions of switched capacitor voltage regulators. Control circuitry 145 can operate to control the switching of switching circuits in switched capacitor circuitry 142 in a respective power switching block 140 based on timing of clock signals (shown in FIG. 2 and FIG. 3A) generated by clock generator 141.

As shown in FIG. 1, voltage regulator 101 can include a feedback circuit 160 on a feedback path (not labeled) coupled between node 102 and an input node (e.g., an inverting input node labeled “−”) of comparator 150. Feedback circuit 160 can include a voltage divider (not shown) coupled to node 102 (associated with voltage V_{OUT}) to generate a voltage (e.g., feedback voltage) V_{OUT_SNS}, such that voltage V_{OUT_SNS} can be a fraction of voltage V_{OUT}.

As shown in FIG. 1, comparator 150 can include input nodes (labeled “+” and “−”) and node (output node) 151. Comparator 150 can include a clocked comparator (e.g., bang-bang PFM comparator). Comparator 150 can operate at a frequency of a clock signal CLK. Clock signal CLK can have a frequency in the gigahertz range (e.g., a frequency of one gigahertz). Comparator 150 can receive voltage V_{OUT} and a voltage V_{REF} at its respective input nodes. Voltage V_{REF} can be a reference voltage provided from a voltage output node of a reference voltage generator (not shown). Voltage V_{REF} can have a value based on the value of voltage V_{OUT_SNS}. For example, voltage V_{REF} can be set to be a target value (e.g., expected value) of voltage V_{OUT_SNS} (where voltage V_{OUT_SNS} is based on voltage V_{OUT}). Comparator 150 can operate to compare the values of voltage V_{OUT_SNS} and V_{REF} at a frequency based on the frequency of clock signal CLK and generate a signal (e.g., comparator output clock signal) CMP_CLK based on the result of the comparison. Voltage regulator 101 can monitor the value (e.g., signal levels) of signal CMP_CLK to control (e.g., regulate) the signal (e.g., voltage or current) at node 102. For example, based on the signal levels of signal CMP_CLK, voltage regulator 101 cause voltage regulating modules 121, 122, and 123 to keep the value voltage V_{OUT} within a target voltage range.

Thus, as shown in FIG. 1, each power switching block 140 has its own clock generator 141. As described below, the clock generator 141 in respective power switching blocks 140 can operate to generate (e.g., locally generate) clock signals (e.g., clock signals CLK_IL and CLK_IL_DT in FIG. 2) for use in switched capacitor circuitry 142 of the same power switching block 140. Therefore, clock generator 141 can be considered a local clock generator with respect to a respective power switching block 140.

As shown in FIG. 1, power switching blocks 140 can be formed in groups (e.g., rows) in which a group of power switching blocks 140 can be located on one side of a respective conductive line 135 (which is part of a respective clock path 131′) and another group of power switching blocks 140 can be located on another side of the respective clock path 131′. As shown in FIG. 1, each of voltage regulating module 121 and 122 can include areas 171 and 172 on opposite sides of a respective conductive line 135 (which is part of a respective clock path 131′). Area 171 is between conductive line 135 and a group (e.g., top four) of power switching blocks 140. Area 172 is between conductive line 135 and another group (e.g., bottom four) of power switching blocks 140. In FIG. 1, the connections (e.g., vertical conductive lines in the view of FIG. 1) between a respective conductive line 135 and a respective power switching block can be considered part of the respective clock path 131′. Thus, as shown in FIG. 1, areas 171 and 172 are without (e.g., void of (e.g., do not include)) an additional clock path in that voltage regulator 101 does not include another clock path in areas 171 and 172 besides clock path 131′. This can indicate that clock path 131′ in a respective voltage regulating module 121 or 122 may be the only clock path between the group (e.g., top four) of power switching blocks 140 adjacent area 171 and the group (e.g., top four) of power switching blocks 140 adjacent area 172 in the respective voltage regulating module (e.g., voltage regulating module 121 or 122).

Thus, in each of voltage regulating module 121 and 122, clock generator 141 of each of power switching blocks 140 may be formed to receive one clock signal (e.g., only one clock signal) which is clock signal CMP_CLK_LCTL propagated on a respective clock path 131′. Since clock generator 141 of each of power switching blocks 140 may be formed to receive one clock signal (e.g., only one clock signal), clock controller 130 may be formed and operate to provide (e.g., generate) one clock signal (e.g., only clock signal CMP_CLK_LCTL) to provide to clock controller 130 of voltage regulating module 121. Thus, in voltage regulator 101, clock controller 130 of voltage regulating module 121 may propagate (on clock path 131′ of voltage regulating module 121) only one clock signal (e.g., clock signal CMP_CLK_LCTL in voltage regulating module 121) to clock generator 141 of each of power switching blocks 140 of voltage regulating module 121. Similarly, clock controller 130 of voltage regulating module 122 may propagate (on clock path 131′ of voltage regulating module 122) only one clock signal (e.g., clock signal CMP_CLK_LCTL in voltage regulating module 122) to clock generator 141 of each of power switching blocks 140 of voltage regulating module 122.

FIG. 2 shows a portion of voltage regulating module 121 of FIG. 1, according to some embodiments described herein. Voltage regulating module 122 (FIG. 1) can include similar (or the same) components as those of voltage regulating module 121 shown in FIG. 2. Thus, for simplicity, detailed description of voltage regulating module 122 is omitted. As shown in FIG. 2, each of power switching blocks 140 can include a node (e.g., clock input node) 225 coupled to node 131 (part of clock path 131′) to receive clock signal CMP_CLK_LCTL, which is provided by clock controller 130 of voltage regulating module 121 of in FIG. 1. Nodes 131 and 225 can be the same node. Clock generator 141 can include a node (e.g., input clock node, that can be the same as node 225) to receive clock signal CMP_CLK_LCTL (a single clock signal) from node 131 (e.g., only a single node 131) and generate clock signals (multiple clock signals) CLK_IL and CLK_IL_DT at nodes 211 and 212, respectively. Nodes 211 and 212 can be called clock output nodes of clock generator 141.

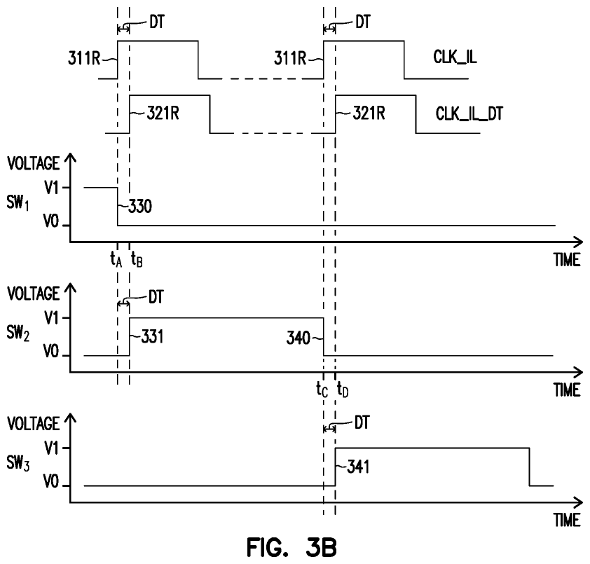

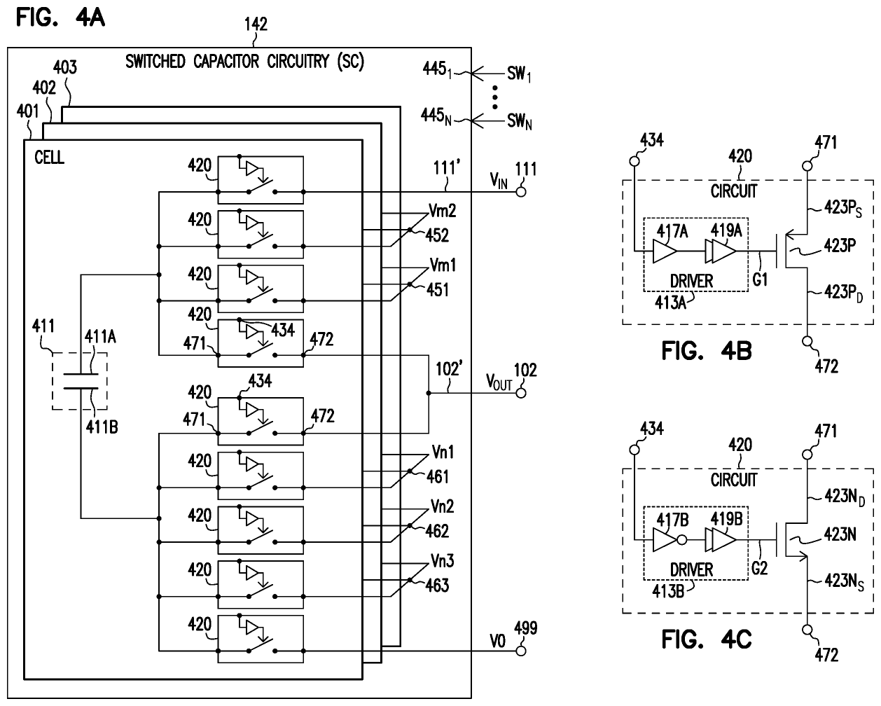

Control circuitry 145 can include input nodes (e.g., clock input nodes, not labeled) coupled to nodes 211 and 212 to receive clock signals CLK_IL and CLK_IL_DT generated (e.g., locally generated) by clock generator 141 in a respective power switching block 140. Control circuitry 145 can operate to generate signals (e.g., switch control signals) SW₁ through SW_{N} based on (e.g., based on timing of) clock signals CLK_IL and CLK_IL_DT from clock generator 141 in a respective power switching block 140. Control circuitry 145 can include nodes (e.g., control output nodes, not labeled) to provide signals SW₁ through SW_{N} to switched capacitor circuitry 142 in a respective power switching block 140. Switched capacitor circuitry 142 can include input nodes (e.g., nodes 4451 through 445_{N} shown in FIG. 4A) coupled to control circuitry 145 to receive signals SW₁ through SW_{N}. As part of regulating voltage V_{OUT} at node 102 (FIG. 1), control circuitry 145 in a respective power switching block 140 can operate to control (e.g., turn on or turn off) the switching of switching circuits (e.g., circuits 420) in switched capacitor circuitry 142 based on (e.g., using) switch signals SW₁ through SW_{N}, which can be generated based on timing of clock signals CLK_IL and CLK_IL_DT.

FIG. 3A shows timing relationships among clock signals CMP_CLK_LCTL, CLK_IL, and CLK_IL_DT of FIG. 2, according to some embodiments described herein. Clock signals CLK_IL and CLK_IL_DT can have the same frequency. The frequency of clock signal CMP_CLK_LCTL can be greater than (e.g., two times greater than) the frequency of each of clock signals CLK_IL and CLK_IL_DT. FIG. 3A shows an example waveform of clock signal CMP_CLK_LCTL. Clock signal CMP_CLK_LCTL may not be a periodic signal. The frequency of clock signal CMP_CLK_LCTL depends on (e.g., follows) the frequency of clock signal CMP_CLK (FIG. 1). The frequency of clock signal CMP_CLK is based on the result of the comparison between the values of voltages V_{OUT_SNS} and V_{REF}. Thus, clock signal CMP_CLK and clock signal CMP_CLK_LCTL (which follows clock signal CMP_CLK) may not be periodic signals. Therefore, clock signals CLK_IL and CLK_IL_DT (which are generated based on clock signal CMP_CLK_LCTL) also may not be periodic signals.

As shown in FIG. 3A, clock signal CMP_CLK_LCTL can have signal levels corresponding to voltages V0 and V1. The signal levels of clock signal CMP_CLK_LCTL can be based on (e.g., can be the same as) the signal levels of clock signal CMP_CLK at output node 151 of comparator 150 of FIG. 1. As shown in FIG. 3A, the signal levels of each of clock signals CLK_IL and CLK_IL_DT can be based on (e.g., can be the same as) the signal levels (e.g., corresponding to voltages V0 and V1) of clock signal CMP_CLK_LCTL. The value of voltage V1 can be based on (e.g., the same as) the value of a supply voltage (e.g., Vcc) of voltage regulator 101. Voltage V0 can be 0V (e.g., ground potential (e.g., Vss)).

As shown in FIG. 3A, each of clock signals CMP_CLK_LCTL, CLK_IL, and CLK_IL_DT has rising edges and falling edges. For example, as shown in FIG. 3A, clock signal CLK_IL has a rising edge 301, a falling edge 303, and a rising edge 305. Clock signal CLK_IL_DT has a rising edge 302, a falling edge 304, and a rising edge 306. As shown in FIG. 3A, rising edges 301 and 302 are closest rising edges (among other rising edges) of respective clock signals CLK_IL and CLK_IL_DT. Rising edges 305 and 306 are closest rising edges (among other rising edges) of respective clock signals CLK_IL and CLK_IL_DT.

In FIG. 3A, times t1, t2, t3, and t4 indicate different points in time in which time t1 occurs before time t2, time t2 occurs before time t3, and time t3 occurs before time t4. As shown in FIG. 3A, rising edge 302 can occur at time t2, which is after a time interval DT1 has elapsed from an occurrence of rising edge 301 at time t1. Rising edge 306 can occur at time t4, which is after a time interval DT2 has elapsed from an occurrence of rising edge 305 at time t3.

As shown in FIG. 3A, each of time interval DT1 and DT2 can be based on (e.g., can correspond to) a time interval between two closest rising edges (e.g., between rising edges 301 and 302 or between rising edges 305 and 306) of respective clock signals CLK_IL and CLK_IL_DT. Each of time intervals DT1 and DT2 can be measured in time units (e.g., picoseconds). Time interval DT1 can be similar to (or the same as) time interval DT2.

Clock signal CLK_IL can have a period T1 measured in time units (e.g., picoseconds). Clock signal CLK_IL_DT can have a period T2 measured in time units (e.g., picoseconds). Period T1 can be equal to period T2. Each of time interval DT1 and DT2 is a fraction of each of periods T1 and T2. For example, each of time interval DT1 and DT2 is not greater than one-eight of each of periods T1 and T2 (e.g., (e.g., DT1≤⅛ T1; DT1≤⅛ T2; DT2≤⅛ T1; and DT1≤⅛ T2). In another example, each of time interval DT1 and DT2 is not greater than one-quarter of each of periods T1 and T2 (e.g., (e.g., DT1≤¼ T1; DT1≤¼ T2; DT2≤¼ T1; and DT1≤¼ T2). In another example, each of time interval DT1 and DT2 is not greater than one-half of each of periods T1 and T2 (e.g., DT1≤½ T1; DT1≤½ T2; DT2≤½ T1; and DT1≤½ T2). In an example, each of time interval DT1 and DT2 can be measured in picosecond (ps) range. For example, each of time interval DT1 and DT2 can be less than 200 ps (e.g., in a range from 60 ps to 100 ps). However, each of time interval DT1 and DT2 can have different values.

The relationship among clock signals CMP_CLK_LCTL, CLK_IL and CLK_IL_DT in other power switching blocks 140 in voltage regulating modules 121 and 122 (FIG. 1) can be similar to (or the same as) the relationship among clock signals CMP_CLK_LCTL, CLK_IL and CLK_IL_DT shown in FIG. 3A. For example, clock signals CLK_IL and CLK_IL_DT in other power switching blocks 140 in voltage regulating modules 121 and 122 can also have time interval DT between two closest rising edges (rising edges 301 and 302 or rising edges 305 and 306) of respective clock signals CLK_IL and CLK_IL_DT. For simplicity, FIG. 3A does not show waveforms of clock signals CMP_CLK_LCTL, CLK_IL and CLK_IL_DT in other power switching blocks 140 in voltage regulating modules 121 and 122 (FIG. 1). However, such waveforms in other power switching blocks 140 can have relationships similar to (or the same as) the relationship among clock signals CMP_CLK_LCTL, CLK_IL and CLK_IL_DT shown in FIG. 3A.

FIG. 3A shows an example for two time intervals DT1 and DT2 in a portion of signals CLK_IL and CLK_IL_DT. However, clock signals CLK_IL and CLK_IL_DT have numerous time intervals like time intervals DT1 and DT2 in other portions (not shown) between occurrence of rising edges (closes rising edges) of respective clock signals CLK_IL and CLK_IL_DT.

Each of time intervals DT1 and DT2 can be called deadtime (or deadtime interval). Each of the time intervals DT1 and DT2 is intentionally created to provide deadtime in a clocking scheme in switched capacitor circuitry of a voltage regulator, such as voltage regulator 101 of FIG. 1. A deadtime such as time intervals DT1 and DT2 allows switched capacitor circuitry 142 (FIG. 2) in a respective power switching block 140 to efficiently control switching circuits (e.g., circuit 420 in FIG. 4A) in the respective power switching block 140. For example, time intervals DT1 and DT2 can prevent transistors in some portions of the switched capacitor circuitry 142 (FIG. 2) from concurrently turning on during a particular time in the operation of the voltage regulator 101. As an example, transistors in a portion of switched capacitor circuitry 142 can be turned off (e.g., completely turned off) based on timing of clock signal CLK_IL before transistors in another portion of switched capacitor circuitry 142 can be turned on based on timing of clock signal CLK_IL_DT. This can improve efficiency (e.g., reduce power loss) of switched capacitor circuitry 142.

FIG. 3A shows an example where time interval (e.g., deadtime) DT1 or DT2 are based on two closest rising edges (e.g., rising edges 301 and 302) of respective clock signals CLK_IL and CLK_IL_DT. However, time interval (e.g., deadtime) DT1 or DT2 can be based on two closest falling edges (e.g., falling edges 303 and 304) of respective clock signals CLK_IL and CLK_IL_DT.

FIG. 3B shows timing relationships among clock signals CLK_IL, CLK_IL_DT, and SW₁ through SW_{N} of FIG. 2, according to some embodiments described herein. In FIG. 3B, clock signals CLK_IL and CLK_IL_DT and time interval (e.g., deadtime) DT are the same those shown in FIG. 3A. Time interval (e.g., deadtime) DT corresponds to time interval DT1 or DT2 of FIG. 3A. As shown FIG. 3B, time interval DT occurs between two closest rising edges 311R and 321R of clock signals CLK_IL and CLK_IL_DT, respectively.

FIG. 3B shows an example for waveforms of three signals SW₁, SW₂, and SW₃ among signals SW₁ through SW_{N} (FIG. 2) for simplicity. Waveforms of signals SW₁ through SW_{N} can have similar patterns like the pattern of waveforms of signals SW₁, SW₂, and SW₃ shown in FIG. 3B. In FIG. 3A, times t_{A}, t_{B}, t_{C}, and t_{D} indicate different points in time in which time t_{A} occurs before time t_{B}, time t_{B} occurs before time t_{C}, and time t_{C} occurs before time t_{D}.

As shown in FIG. 3B, signals SW₁, SW₂, and SW₃ can include respective falling edges 330 and 340, and rising edges 331 and 341. Falling edges 330 and 340 can occur based on (e.g., aligned with) respective rising edges 311R of signal CLK_IL. Rising edges 331 and 341 can occur based on (e.g., can be aligned with) respective rising edges 321R of signal CLK_IL_DT. As shown in FIG. 3B, the falling and rising edges of signals SW₁, SW₂, and SW₃ can occur one after another (e.g., occur sequentially) based on time interval DT. For example, falling edge 330 of signals SW₁ occurs at time signal t_{A}. Rising edge 331 of signal SW₂ occurs at time signal tp. The time interval between times t_{A} and t_{B} is time interval TD. In another example, as shown in FIG. 3B, falling edge 340 of signals SW₂ occurs at time t_{C}. Rising edge 341 of signal SW₃ occurs at time signal tp. The time interval between times t_{C} and t_{D} is time interval TD. Based on this pattern, the falling and rising edges of signals SW₁ through SW_{N} can occur one after another based on time intervals DT at different portions of signals CLK_IL and CLK_IL_DT, as shown in FIG. 3B.

The techniques described above with reference to FIG. 1, FIG. 2, and FIG. 3A allow a voltage regulator to have improvements and benefits over some conventional switched capacitor converters. For example, some conventional switched capacitor converters may use a main clock generator to generate many clock signals (e.g., for use in a time-interleaved clocking scheme) and propagate the clock signals on multiple clock paths to switched capacitor blocks of the switched capacitor converter. However, generating many clock signals and propagating them on many clock paths to the switched capacitor blocks in the switched capacitor converter may need a relatively large amount of power. The power consumption would be even larger if the clock signals are propagated on many clock paths over a relatively long distance (e.g., in millimeter range) to the switched capacitor blocks.

In voltage regulator 101 as described above, since only one clock signal (e.g., clock signal CMP_CLK_LCTL) is generated for propagating to power switching blocks 140, voltage regulator 101 may consume a relatively lower amount of power (in comparison to the technique used in the conventional switched capacitor converter) to generate and propagate the clock signal to power switching blocks 140.

FIG. 4A shows switched capacitor circuitry 142 of a respective power switching block 140 of FIG. 1 and FIG. 2, according to some embodiments described herein. FIG. 4B and FIG. 4C show two circuit structures (e.g., driver and transistors) of a circuit 420 of FIG. 4A, according to some embodiments described herein.

As shown in FIG. 4A, switched capacitor circuitry 142 can circuits (switching circuits) 420, and input nodes (e.g., clock input nodes) 4451 through 445_{N} to receive signals SW₁ through SW_{N}. As described above, signals SW₁ through SW_{N} can be generated by control circuitry 145 of FIG. 1 and FIG. 2 based on clock signals CLK_IL and CLKI_IL_DT, which can be generated by clock generator 141 of FIG. 1 and FIG. 2. In FIG. 4A, different signals among signals SW₁ through SW_{N} can be used to control (e.g., turn on or turn off) different circuits 420 of switched capacitor circuitry 142. Thus, circuits 420 can be turned on or turned off at different times based on the timing of signals SW₁ through SW_{N}. As described above (e.g., FIG. 2, FIG. 3A, and FIG. 3B), signals SW₁ through SW_{N} can have a time interval (e.g., deadtime) DT based on time interval (e.g., deadtime) DT1 or DT2 generated by clock signal generator 141 of FIG. 1 and FIG. 2.

As shown in FIG. 4A, switched capacitor circuitry 142 can include node (e.g., voltage input node) 111′ and node (e.g., voltage output node) 102′. Node 111′ can correspond (e.g., can be coupled to) to one of nodes 111A, 111B, and 111C of respective voltage regulating modules 121, 122, and 123 in FIG. 1. For example, node 111′ of switched capacitor circuitry 142 of voltage regulating module 121 can correspond to (e.g., can be coupled to) to node 111A of FIG. 1. In another example, node 111′ of switched capacitor circuitry 142 of voltage regulating module 122 can correspond to (e.g., can be coupled to) to node 111B of FIG. 1.

Node 102′ can correspond (e.g., can be coupled to) to one of nodes 102A, 102B, and 102C of respective voltage regulating modules 121, 122, and 123 in FIG. 1. For example, node 102′ of switched capacitor circuitry 142 of voltage regulating module 121 can correspond to (e.g., can be coupled to) to node 102A of FIG. 1. In another example, node 102′ of switched capacitor circuitry 142 of voltage regulating module 122 can correspond to (e.g., can be coupled to) to node 102B of FIG. 1.

As shown in FIG. 4A, switched capacitor circuitry 142 can include cells (e.g., switched capacitor cells) 401, 402, and 403, each of which can include circuits (e.g., switching circuits) 420 and at least one capacitor 411. FIG. 4A symbolically shows circuit elements of each circuit 420. Each circuit 420 in FIG. 4A can be either circuit 420 in FIG. 4B or circuit 420 in FIG. 4C.

FIG. 4A shows switched capacitor circuitry 142 including three cells 401, 402, and 403 as an example. However, switched capacitor circuitry 142 can include a different number of cells. The cells (e.g., cells 401, 402, and 403) include similar (or the same) circuit elements (e.g., like capacitor 411 and circuits 420).

For simplicity, the following description describes circuit elements (e.g., circuits 420 and capacitor 411) of cell 401. Other cells (e.g., cells 402 and 403) of switched capacitor circuitry 142 in FIG. 4A have similar circuit elements. Further, each of switched capacitor circuitry (SC) 142 in a respective power switching block 140 in FIG. 1 can also have cells including circuits and capacitor such as cell 401 and circuits 420 and capacitor 411, respectively, of FIG. 4A.

FIG. 4A shows cell 401 including capacitor 411 (e.g., a single flying capacitor) coupled to circuits 420 as an example. However, cell 401 can include multiple capacitors (e.g., multiple flying capacitors) coupled to circuits 420. As shown in FIG. 4A, capacitor 411 can include a capacitor plate (e.g., top plate) 411A and a capacitor plate (e.g., bottom place) 411B. Capacitor 411 can include a metal-in-metal (MiM) capacitor, a transistor-based capacitor (e.g., capacitor formed by metal-oxide semiconductor field-effect transistor (MOSFET) devices), or other types of capacitors (e.g., other on-die (e.g., on-semiconductor die) or on-chip capacitors). Thus, capacitor 411 can be an on-die or on-chip or capacitor, such that capacitor 411 can be located in (e.g., formed on or formed in) the same IC die on which other components (e.g., circuits 420) of switched capacitor circuitry 142 are located.

In FIG. 4A, nodes 102 and 111 (associated with voltages V_{OUT} and V_{IN}, respectively) are the same nodes of voltage regulator 101 shown in FIG. 1. In FIG. 4A, node 499 (associated with voltage V0) can be part of a ground connection of switched capacitor circuitry 142. Thus, voltage V0 can include ground potential (GND). In FIG. 4A, node 111′ (which is coupled to node 111) can be an input node (e.g., voltage input node) of a respective power switching block 140 that includes switched capacitor circuitry 142 of FIG. 4A. Node 102′ (which is coupled to node 102) can be an output node (e.g., voltage output node) of a respective power switching block 140 that includes switched capacitor circuitry 142 of FIG. 4A.

In FIG. 4A, nodes (e.g., voltage rail nodes) 451 and 452 can be part of respective voltage rails (internal voltage rails) that can provide voltages Vm1 and Vm2. Nodes 461, 462, and 463 can be part of respective voltage rails (internal voltage rails) that can provide voltages Vn1, Vn2, and Vn3.

Voltages Vm1 and Vm2 can have different values and can be less than voltage V_{IN} and greater than voltage V_{OUT} (e.g., V_{OUT}<Vm1<Vm2<V_{IN}). Voltages Vn1, Vn2, and Vn3 can have different values and can be less than voltage V_{OUT} and greater than voltage V0 (e.g., V0<Vn3<Vn2<Vn1<V_{OUT}). FIG. 4A shows a specific number (e.g., five) of internal voltage rails (associated with five voltages Vm1, Vm2, Vn1, Vn2, and Vn3) of switched capacitor circuitry 142 as an example. However, the number internal voltage rails of switched capacitor circuitry 142 can vary. Further, FIG. 4A shows a specific number (e.g., four) of circuits 420 between plate 411A and respective nodes 102 and 111 and a specific number (e.g., five) of circuits 420 between plate 411B and respective nodes 102 and 499 as an example. However, the number of circuits 420 between plate 411A and nodes 102 and 111 and the number of circuits 420 between plate 411B and nodes 102 and 499 can vary.

As shown in FIG. 4A, each of circuits 420 can include nodes 471 and 472 and a node (e.g., control node) 434. For simplicity, nodes 434, 471, and 472 of only two circuits 420 are labeled in FIG. 4A. As shown in FIG. 4A, each of circuits 420 can be coupled between one of plates 411A and 411B of capacitor 411 and one of nodes 111, 102, 451, 452, 461, 462, 463, and 499. For example, node 471 of a respective circuit 420 can be coupled to one of plates 411A and 411B of capacitor 411, and node 472 of a respective circuit 420 can be coupled to one of nodes 111, 102, 451, 452, 461, 462, 463, and 499.

Node 434 of circuit 420 can be structured to (e.g., configured to) receive one of signals SW₁ through SW_{N} (which are generated based on clock signal CLK_IL and CLK_IL_DT). In FIG. 4A, circuit 420 can respond to a control signal at node 434 to form a conductive path between nodes 471 and 472 through a respective circuit 420. Such a conductive path can be coupled to one of plates 411A and 411B of capacitor 411 and one of nodes 111, 102, 451, 452, 461, 462, 463, and 499.

As shown in FIG. 4B, circuit 420 can include a driver 413A coupled to a transistor 423P. Driver 413A can include a buffer (buffer circuit) 417A coupled to a buffer (buffer circuit) 419A. Each of buffers 417A and 419A can include complementary metal-oxide semiconductor (CMOS) transistors (not shown). In an alternative structure of circuit 420 in FIG. 4B, driver 413A can include fewer or more circuit elements than the number of circuit elements shown in FIG. 4B. For example, in an alternative structure of circuit 420 in FIG. 4B, one of buffers 417A and 419A can be eliminated.

In FIG. 4B, transistor 423P can include a field-effect transistors (FET) that can be a p-type transistor. For example, transistor 423P can include an n-channel metal-oxide semiconductor field-effect transistor (PMOS transistor). Transistor 423P can include another kind of transistor. As shown in FIG. 4B, transistor 423P can include a gate (gate terminal) G1, and terminals (non-gate terminals) 423P_{D} and 423P_{S}. Terminals 423P_{D} and 423P_{S} can correspond the drain and source, respectively, of transistor 423P. In this description, source and drain terminals of a transistor are used interchangeably.

Terminal 423P_{S} and 423P_{D} of transistor 423P can be coupled to nodes 471 and 472, respectively, of circuit 420. Thus, terminals 423P_{S} and 423P_{D} can be respectively coupled to (e.g., coupled between) one of plates 411A and 411B (FIG. 4A) of capacitor 411 and one of nodes 111, 102, 451, 452, 461, 462, 463, and 499. Circuit 420 (FIG. 4B) can respond to the control signal (e.g., one of signals SW₁ through SW_{N}) at node 434 to control the switching (e.g., turn on or turn off) of transistor 423P.

Circuit 420 in FIG. 4B can respond to the control signal (e.g., one of signals SW₁ through SW_{N}) at node 434 to control the switching (e.g., turn on or turn off) of transistor 423P. For example, during one signal level (e.g., level corresponding to voltage V0) of the control signal at node 434, circuit 420 can turn on transistor 423P and form a conductive path between nodes 471 and 472 (through transistor 423P). Charge can be transferred between node 471 and 472 when transistor 423P is turned on. In another example, during another signal level (e.g., level corresponding to voltage V1) of the control signal node 434, circuit 420 can turn off transistor 423P and disable a conductive path between nodes 471 and 472. Charge transfer between node 471 and 472 through transistor 423P is disabled when transistor 423P is turned off.

As shown in FIG. 4C, circuit 420 can include a driver 413B coupled to a transistor 423N. Driver 413B can include an inverter 417B coupled to a buffer (buffer circuit) 419B. Each of inverter 417B and buffer 419B can include complementary metal-oxide semiconductor (CMOS) transistors (not shown). In an alternative structure of circuit 420 in FIG. 4B, driver 413A can include fewer or more circuit elements than the number of circuit elements shown in FIG. 4B. For example, in an alternative structure of circuit 420 in FIG. 4C, buffer 419B can be eliminated, such that the output node of driver 417B can be directly coupled to gate G2 of transistor 423N.

In FIG. 4C, transistor 423N can include a field-effect transistor (FET) that can be an n-type transistor. For example, transistor 423N can include an n-channel metal-oxide semiconductor field-effect transistor (NMOS transistor). Transistor 423N can include another kind of transistor.

As shown in FIG. 4C, transistor 423N can include gate (gate terminal) G2, and terminals (non-gate terminals) 423N_{D} and 423N_{S}. Terminals 423N_{D} and 423N_{S} can correspond to the drain and source, respectively, of transistor 423N. Terminal 423_{D} and 423_{S} of transistor 423N can be coupled to nodes 471 and 472, respectively, of circuit 420. Thus, terminals 423N_{D} and 423N_{S} can be respectively coupled to (e.g., coupled between) one of plates 411A and 411B (FIG. 4A) of capacitor 411 and one of nodes 111, 102, 451, 452, 461, 462, 463, and 499.

Circuit 420 in FIG. 4C can respond to the control signal (e.g., one of signals SW₁ through SW_{N}) at node 434 to control the switching (e.g., turn on or turn off) of transistor 423N. For example, during one signal level (e.g., level corresponding to voltage V1) of the control signal at node 434, circuit 420 can turn on transistor 423N and form a conductive path between nodes 471 and 472 (through transistor 423N). Charge can be transferred between node 471 and 472 when transistor 423N is turned on. In another example, during another signal level (e.g., level corresponding voltage V0) of the control signal at node 434, circuit 420 can turn off transistor 423N and disable a conductive path between nodes 471 and 472. Charge transfer between node 471 and 472 through transistor 423N is disabled when transistor 423N is turned off.

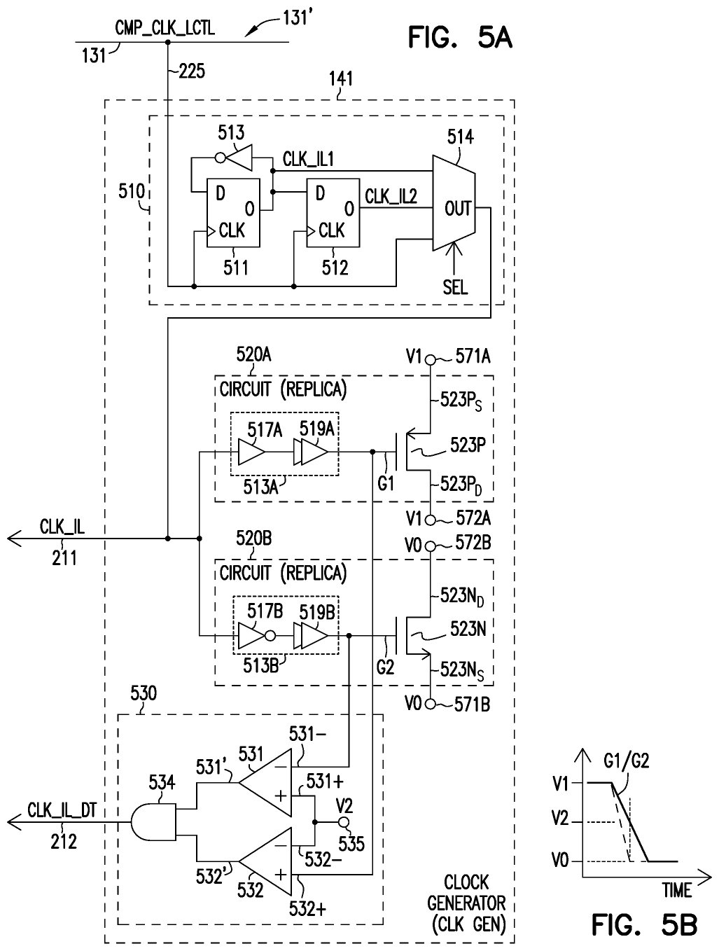

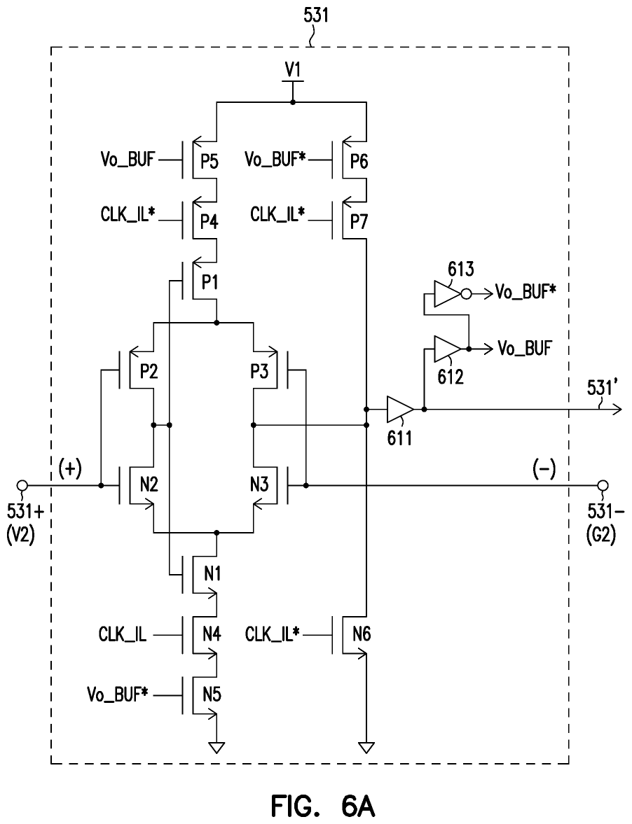

Thus, as described above, each of circuit 420 of switched capacitor circuitry 142 can be either circuit 420 of FIG. 4B or circuit 420 of FIG. 4C. As described below with reference to FIG. 5A, as part of generating an adaptive deadtime associated with clock signals CLK_IL and CLK_IL_DT (FIG. 3A), clock generator 141 can include circuits that are based on (e.g., replicas of) circuit 420 of FIG. 4B and circuit 420 of FIG. 4C.

FIG. 5A shows clock generator 141 of FIG. 1 and FIG. 2, according to some embodiments described herein. FIG. 5B is a timing diagram showing relative voltage levels associated with gate voltage crossing detection performed by clock generator 141 of FIG. 5A. As shown in FIG. 5A, clock generator 141 can include a circuit 510, circuits (e.g., replica circuits) 520A and 520B, and a circuit 530. Circuit (e.g., time-interleaved clock generating circuit) 510 can operate to generate clock signals CLK_IL and CLK_IL1 and CLK_IL2 based on clock signal CMP_CLK_LCTL. Clock signals CLK_IL1, CLK_IL2, and CMP_CLK_LCTL can provide a time-interleaved clocking scheme for use in switched capacitor circuitry 142 of voltage regulator 101 in FIG. 1. The time-interleaved clocking scheme including clock signals CLK_IL1, CLK_IL2, and CMP_CLK_LCTL allows switching circuits of different portions (e.g., different groups of power switching blocks 120 in FIG. 1) to be controlled based on different clock signals (among CLK_IL1, CLK_IL2, and CMP_CLK_LCTL). As shown in FIG. 5A, circuit 510 can include a selector (e.g., a multiplexer 514) to select among CLK_IL1, CLK_IL2, and CMP_CLK_LCTL to be clock signal CLK_IL. Thus, in the interleaved clocking scheme, different power switching blocks 120 in FIG. 1 may select different clock signals among clock signals CLK_IL1, CLK_IL2, and CMP_CLK_LCTL to be their respective clock signals CLK_IL.

The combination of circuits 520A, 520B, and 530 of clock generator 141 in FIG. 5A can generate an adaptive deadtime (e.g., time intervals DT1 and DT2 in FIG. 3A) in the clocking scheme (e.g., time-interleaved clocking scheme) of voltage regulator 101. Circuits 520A and 520B are replicas (replica circuits) of two of circuits 420 of switched capacitor circuitry 142 (FIG. 4A and FIG. 1) to allow clock generator 141 of FIG. 5A tracking behaviors (e.g., turning on or turning off behaviors) of circuits 420 in switched capacitor circuitry 142 (FIG. 1 and FIG. 4A) under different conditions (e.g., PVT). Such a tracking can provide deadtime (e.g., time intervals DT1 and DT2 in FIG. 3A) that is adaptive to the switching of circuits 420 in switched capacitor circuitry 142. Circuits 520A and 520B allow clock generator 141 to perform detection of turning off (e.g., zero-crossing) behaviors of circuit elements (e.g., transistors 423) of circuits 420 in switched capacitor circuitry 142 (FIG. 4A) to generate deadtime that can be adaptively changed based on the detection.

Clock generator 141 of FIG. 4A can be located locally at a respective power switching block 120 of FIG. 1. Thus, each of power switching blocks 120 can generate (e.g., locally generate) its own clock signals CLK_IL and CLK_IL_DT based on the same clock signal (e.g., input clock signal) CMP_CLK_LCTL. In the example of voltage regulator 101 of FIG. 1 where voltage regulating module 121 includes eight power switching blocks 120, eight pair of clock signals CLK_IL and CLK_IL_DT (each pair includes two clock signals CLK_IL and CLK_IL_DT) can be generated (e.g., locally generated) by eight respective clock generators 141 in eight respective power switching blocks 120 in voltage regulating module 121. Similarly, there can be eight pair of clock signals CLK_IL and CLK_IL_DT generated (e.g., locally generated) by eight respective clock generators 141 in eight respective power switching blocks 120 in voltage regulating module 122.

As shown in FIG. 5A, circuit 510 can include an input node coupled to node (e.g., clock node) 225 to receive clock signal CMP_CLK_LCTL from node 131 of clock path 131′. As described above with reference to FIG. 1 and FIG. 2, clock signal CMP_CLK_LCTL can be generated by clock controller based on clock signal CMP_CLK from comparator 150 (FIG. 1). As shown in FIG. 5A, circuit 510 can include D flip-flops 511 and 512 (each of which can include an input D, a clock input CLK, and an output O (e.g., Q output)), inverter 513, and multiplexer (MUX) 514, connected as shown in FIG. 5A to generate clock signals CLK_IL1 and CLK_IL2 based on clock signal CMP_CLK_LCTL. MUX 514 can be controlled by selection information (e.g., digital code) SEL to select one of clock signals CMP_CLK_LCTL, CLK_IL1 and CLK_IL2, to be clock signal CLK_IL at an output node OUT of MUX 514. Output node OUT can be coupled to node (e.g., clock output node) 211 to provide clock signal CLK_IL.

As shown in FIG. 5A, circuit 520A can include a driver 513A coupled to a transistor 523P. Driver 513A can include a buffer 517A and buffer 519A. Driver 513A can include an input node coupled to node 211 and an output node coupled to a gate G1 of transistor 523P. Transistor 523P can include an p-type (e.g., PMOS) transistor. The structure (physical structure) of circuit 520A can be based on the structure (physical structure) of a selected circuit 420 of FIG. 4A. The selected circuit 420 can be one of circuits 420 of switched capacitor circuitry 142 of FIG. 4A.

Since transistor 523P in circuit 520A in FIG. 5A includes a p-type transistor, the selected circuit 420 can include a p-type transistor like the structure of circuit 420 shown in FIG. 4B. Thus, in FIG. 5A, the structure of driver 513A and transistor 523P can be based on the structure (e.g., can be a replica of the structure) of driver 413A and transistor 423P, respectively, of circuits 420 of FIG. 4B. Therefore, the structures of buffer 517A and buffer 519A (of driver 513A) can be based on the structures (e.g., can be replicas of the structures) of buffer 517A and buffer 519A, respectively, of driver 414A of FIG. 4B.

As shown in FIG. 5A, transistor 523P can include a gate G1, and terminals (non-gate terminals) 523P_{S} and 523P_{D} (e.g., source and drain, respectively, of transistor 523P). Terminals 523P_{S} and 523P_{D} can correspond to terminals 423P_{S} and 423P_{D} of transistor 423P of FIG. 4B. Terminals 523P_{S} and 523P_{D} can be coupled to nodes 571A and 572A, respectively. Nodes 571A and 572A can correspond to nodes 471 and 472 of FIG. 4B. In FIG. 5A, nodes 571A and 572A can be coupled to voltage V1 (e.g., supply voltage Vcc).

As shown in FIG. 5A, circuit 520B can include driver 513B coupled to a transistor 523N. Driver 513B can include an inverter 517B and buffer 519B. Driver 513B can include an input node coupled to node 211 and an output node coupled to gate G2 of transistor 523N. Transistor 523N can include an n-type (e.g., NMOS) transistor. The structure (physical structure) of circuit 520B can be based on the structure (physical structure) of a selected circuit 420 of FIG. 4A. The selected circuit 420 can be one of circuits 420 of switched capacitor circuitry 142 of FIG. 4A. Since transistor 523N in circuit 520B in FIG. 5B includes an n-type transistor, the selected circuit 420 can include an n-type transistor like the structure of circuit 420 shown in FIG. 4C. Thus, in FIG. 5A, the structure of driver 513B and transistor 523N can be based on the structure (e.g., can be a replica of the structure of) of driver 413B and transistor 423N, respectively, of circuits 420 of FIG. 4C. Therefore, the structures of inverter 517B and buffer 519B (of driver 513B) can be based the structures (e.g., can be replicas of the structures) of inverter 517B and buffer 519B, respectively, of driver 413B of FIG. 4B.

As shown in FIG. 5A, transistor 523N can include a gate G2, and terminals (non-gate terminals) 523N_{S} and 523N_{D} (e.g., source and drain, respectively, of transistor 523N). Terminals 523N_{S} and 523N_{D} can correspond to terminals 423N_{S} and 423N_{D} of transistor 423N of FIG. 4C. As shown in FIG. 5A, terminals 523N_{S} and 523N_{D} can be coupled to nodes 571B and 572B, respectively. Nodes 571B and 572B can correspond to nodes 471 and 472 of FIG. 4C. Nodes 571B and 572B can be coupled to voltage V0 (e.g., ground potential).

As shown in FIG. 5A, circuit 530 can include input nodes coupled to gates G1 and G2 of transistors 523P and 523N, respectively. Circuit 530 also includes input nodes coupled to a node (e.g., voltage node) 535, which can receive a voltage V2. Circuit 530 can include an output node coupled to node 212 to provide clock signal CLK_IL_DT.

Circuit 530 can include comparators 531 and 532 and a logic gate (e.g., AND gate) 534. Comparator 531 can include input nodes 531− and 531+ that can correspond to “−” and “+” input nodes, respectively, of comparator 531. Comparator 532 can include input nodes 532− and 532+ that can correspond to “−” and “+” input nodes, respectively, of comparator 532. In comparators 531 and 532, “−” and “+” input nodes can be called inverting input node and non-inverting input node, respectively.

As shown in FIG. 5A, nodes 531− and 532+ of comparator 531 and 523, respectively, can be coupled to gates G2 and G1, respectively, of transistors 523N and 523P. Nodes 531+ and 532− of comparator 531 and 523, respectively, can be coupled to a node 535 (associated with voltage V2). Voltage V2 can be based on the voltage V1 (e.g., the supply voltage of clock generator 141). As shown in FIG. 5B, voltage V2 can be one-half of voltage V1 (e.g., V2=½ V1). As an example, voltage V2 can be 0.5V (e.g., V2=0.5V) and voltage V1 is 1V (e.g., V1=1V). Each of comparators 531 and 532 can be a relatively high-speed comparator with low quiescent current to instantaneously detect the voltages at gates G1 and G2 crossing a voltage (e.g., voltage V2 in the example of FIG. 5A) to generate signal CLK_IL_DT with deadtime (e.g., time intervals DT1 and DT2 in FIG. 3A).

In FIG. 5A, the rising edges of clock signals CLK_IL1 and Clk_IL_2 generated by circuit 510 can occur at different times. Voltage regulator 101 may use different portions (e.g., different groups) of power switching blocks 140 to control operations (e.g., controlling voltage ripple of voltage V_{OUT} at node 102 in FIG. 1) of voltage regulating modules 121 and 122. The different portions of power switching blocks 140 can be activated at different times based on timing of different clock signals (e.g., clock signals CLK_IL1 and CLK_IL2 in FIG. 5A). For examples, one portion (e.g., the top four power switching blocks 140) of voltage regulating modules 121 and 122 FIG. 1 may be controlled (e.g., activated) based on clock signal CLK_IL1 of FIG. 5A, and another portion (e.g., the bottom four power switching blocks 140) of voltage regulating modules 121 and 122 in FIG. 1 may be a controlled (e.g., activated) based on clock signal CLK_IL2 of FIG. 5A.

In the above example, MUX 514 (FIG. 5A) of clock generator 141 in one portion (e.g., the top four power switching blocks 140) of voltage regulating modules 121 and 122 in FIG. 1 may be provided with selection information SEL (e.g., SEL=CODE1) that is different from selection information SEL (e.g., SEL=CODE2) provided to MUX 514 (FIG. 5A) of clock generator 141 of another portion (e.g., the bottom four power switching blocks 140) of voltage regulating modules 121 and 122 in FIG. 1. Values CODE1 an CODE2 can be different digital values. Selection information SEL having value CODE 1 (e.g., SEL=CODE1) can cause MUX 514 (FIG. 5A) of clock generator 141 of the top four power switching blocks 140 (based on the example above) in voltage regulating modules 121 and 122 (FIG. 1) to select clock signal CLK_IL1 to be clock signal CLK_IL at node 211.

Selection information SEL having value CODE2 (e.g., SEL=CODE2) can cause MUX 514 (FIG. 5A) of clock generator 141 of the bottom four power switching blocks 140 (based on the example above) in voltage regulating modules 121 and 122 (FIG. 1) to select clock signal CLK_IL2 to be clock signal CLK_IL at node 211.

In the above example, the values of selection information SEL provided to MUX 514 (FIG. 5A) can be different in different portions of power switching blocks 140 within the same voltage regulating mode. However, selection information SEL can be the same in power switching blocks 140 within the same voltage regulating mode. For example, MUX 514 (FIG. 5A) of clock generator 141 of power switching blocks 140 of voltage regulating module 121 (FIG. 1) may be provided with the same selection information SEL (e.g., SEL=CODE1). In this example, MUX 514 of clock generator 141 of all power switching blocks 140 of voltage regulating module 122 (FIG. 1) may be provided with the same selection information SEL (e.g., SEL=CODE2) that is different from selection information SEL (e.g., SEL=CODE1) provided to MUX 514 of clock generator 141 of power switching blocks 140 in voltage regulating module 121. In this example, selection information SEL having value CODE 1 (e.g., SEL=CODE1) can cause MUX 514 of clock generator 141 of power switching blocks 140 in voltage regulating module 121 (FIG. 1) to select clock signal CLK_IL1 to be clock signal CLK_IL at node 211. Selection information SEL having value CODE2 (e.g., SEL=CODE2) can cause MUX 514 of clock generator 141 of power switching blocks 140 in voltage regulating module 122 (FIG. 1) to select clock signal CLK_IL2 to be clock signal CLK_IL at node 211. The values of selection information SEL can be provided (e.g., can be set) by control circuitry (not shown) of voltage regulator 101 (FIG. 1).

A voltage regulator like voltage regulator 101 of FIG. 1 can have control circuitry (not shown) to control ripple of the output voltage (e.g., voltage V_{OUT}) and load transient at node 102 (FIG. 1). In the above example, MUX 514 (FIG. 5A) can be set (e.g., provided with selection information SEL=CODE1 or CODE2) to select either clock signal CLK_IL or clock signal CLK_IL_DT if controlling ripple of the output voltage (e.g., voltage V_{OUT}) is more favorable than controlling a response to load transient at node 102. However, if a relatively fast load transient response is more favorable than controlling of ripple of output voltage 102, MUX 514 (FIG. 5A) can be set to select signal CMP_CLK_LCTL to be clock signal CLK_IL at node 211 (FIG. 5A)

In FIG. 5A, clock generator 141 can include a bypass feature to bypass selection of clock signals CLK_IL1 and CLK_IL2 and select clock signal CMP_CLK_LCTL to be clock signal CLK_IL at node 211. For example, in a bypass mode (e.g., controlled by control circuitry of voltage regulator 101), MUX 514 (FIG. 5A) of clock generator 141 may be provided with selection information SEL (e.g., SEL=CODE3, where value CODE3 can be a digital value). Selection information SEL having value CODE3 (e.g., SEL=CODE3) can cause MUX 514 of clock generator 141 to select clock signal CMP_CLK_LCTL to be clock signal CLK_IL at node 211.

The sizes of transistor 523P and 523N in FIG. 5A can be based on the sizes of transistor 423P (FIG. 4B) and transistor 423N (FIG. 4C), respectively. The size of a transistor (e.g., transistor 423P or 423N) can be based on the channel width and channel length (e.g., based on channel width to channel length ratio) of the transistor. In an example, transistors 523P and 523N can have the same size as transistors 423P and 423N, respectively. In this example, clock generator 141 can operate to detect voltages at gates G1 and G2 crossing voltage V0 (e.g., V0=0V in FIG. 5B) to generate a clock signal with deadtime (e.g., time intervals DT1 and DT2 in FIG. 3A).

In another example, the size of transistor 523P can be structured (e.g., formed) to be greater (e.g., two times greater than) the size as transistor 423P, and the size of transistor 523N can be structured (e.g., formed) to be greater (e.g., two times greater than) the size as transistor 423N. By structuring (e.g., forming) the sizes of transistors 523P and 523N to be greater (e.g., two times greater) than the sizes of transistor 423P and 423N, respectively, clock generator 141 can operate to detect the voltages at gates G1 and G2 crossing voltage V2 (instead of voltage V0) to generate a clock signal with deadtime (e.g., time intervals DT1 and DT2 in FIG. 3A). As shown in FIG. 5B, voltage V2 can be one-half of voltage V1 (e.g., voltage V2 can be a mid-rail voltage). Thus, in this example, by structuring the sizes of transistors 523P and 523N to be greater (e.g., two times greater) than the sizes of transistor 423P and 423N, respectively, detection of the voltages at gates G1 and G2 crossing at voltage V0 (e.g., zero-voltage crossing) can be moved to detection of the voltages at gates G1 and G2 crossing at voltage V2 (e.g., mid-rail voltage crossing) crossing detection.

Selecting among circuits 420 of FIG. 4A to be the selected circuit 420 to form replica circuit 520A can be based on the switching speed of transistors 423P of circuits 420 (FIG. 4B). In an example, a transistor 423P (among transistors 423P of circuits 420 in FIG. 4B) that has a relatively slower switching speed (e.g., a slowest switching speed) can be selected. Thus, circuit 520A can be a replica of the selected circuit 420 that includes transistor 423P having a relatively slower switching speed. The slow transistor 423P can be selected from circuits 420 (e.g., all circuits 420) in the voltage regulating modules 121, 122, and 123 of voltage regulator 101. Clock generators 141 of power switching blocks 140 in voltage regulating modules 121, 122, and 123 of voltage regulator 101 can have the same replica circuit (e.g., circuit 520A) that is based on circuit 420P of FIG. 4B.

Selecting among circuits 420 of FIG. 4A to be the selected circuit 420 to form replica circuit 520B can be based on the switching speed of transistors 423N of circuits 420 (FIG. 4C). In an example, a transistor 423N (among transistors 423N of circuits 420 in FIG. 4C) that has a relatively slower switching speed (e.g., a slowest switching speed) can be selected. Thus, circuit 520B can be a replica of the selected circuit 420 that includes transistor 423N having a relatively slower switching speed. The slow transistor 423N can be selected from circuits 420 (e.g., all circuits 420) in the voltage regulating modules 121, 122, and 123 of voltage regulator 101. Clock generators 141 of power switching blocks 140 in voltage regulating modules 121, 122, and 123 of voltage regulator 101 can have the same replica circuit (e.g., circuit 520B) that is based on circuit 420N of FIG. 4C.

As shown in FIG. 5A and FIG. 4B, the structure of circuit 520A can be based on the structure of circuits 420, such that circuit 520A has the same number (quantity) of circuit elements and transistor types as circuit 420. For example, as shown in FIG. 5A, circuit 520A has three circuit elements including buffer 517A, buffer 519A, and transistor 523P. In FIG. 4B, circuit 420 also has three circuit elements including buffer 417A, buffer 419A, and transistor 423P. Similarly, the structure of circuit 520B can be based on the structure of circuits 420, such that circuits 520B has the same number (quantity) of circuit elements and transistor type of transistor 523N as circuit 420. For example, as shown in FIG. 5A, circuit 520B has three circuit elements including inverter 517B, buffer 519B, and transistor 523N. In FIG. 4C, circuit 420 also has three circuit elements including buffer inverter 417B, buffer 419B, and transistor 523N.

The techniques described above associated with generating deadtime using clock generator 141 of FIG. 5A allow a voltage regulator to have improvements and benefits over some conventional switched capacitor converters. For example, some conventional switched capacitor converters have a fixed deadtime associated with clock signals used in switched capacitor circuitry in these conventional switched capacitor converters. Such a fixed deadtime is usually set at a relatively large value (e.g., large guard banded value) to cover variations (e.g., PVT) in switched capacitor circuitry of the conventional switched capacitor converters. A large deadtime can cause the current density of the conventional switched capacitor converters to be below a relatively high value (e.g., optimal value).

In clock generator 141 of FIG. 5A, the adaptive deadtime can cover variations (variations in PVT) in the switching circuits (e.g., circuit 420 in FIG. 4A). Thus, fixed deadtime (with large guard band) may be unnecessary. Since the adaptive deadtime is based on zero-crossing of the switching circuits (e.g., circuit 420) by ways of the replica circuits (e.g., circuits 520A and 520B in FIG. 5A), the adaptive deadtime can be relatively small (e.g., smaller than a fixed deadtime). A small deadtime allows the current density of voltage regulator 101 to be relatively higher (e.g., at an optimal value) in comparison to some conventional switched capacitor converters.

As described above, since clock controller 130 in FIG. 1 may generate only one clock signal (e.g., clock signal CMP_CLK_LCTL), power consumption associated propagating the clock signal to power switching blocks 140 within is relatively low. Since deadtime and clock signals for the time-interleaved clocking scheme can be locally generated by clock generator 141 in FIG. 1, in a respective power switching block 140, voltage regulator 101 can be scaled with relatively less complexity to include higher number power switching blocks 140, a higher number of clock signals for the time-interleaved clocking scheme, or both.

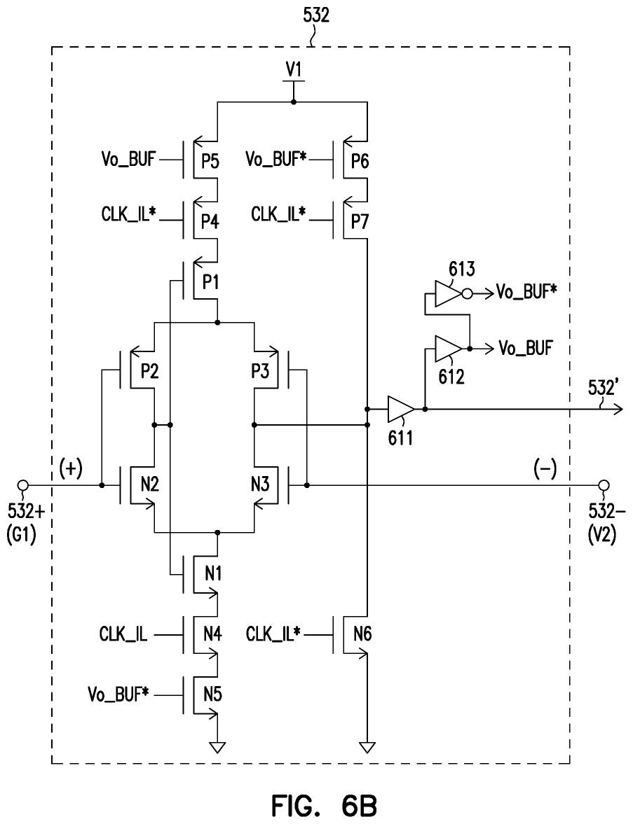

FIG. 6A shows comparator 531 of clock generator 141 of FIG. 5A, according to some embodiments described herein. As shown in FIG. 6A, comparator 531 can include transistors (e.g., PMOS transistors) P1 through P7, transistors (e.g., NMOS transistors) N1 through N6, buffers 611 and 612, and inverter 613. Input node 531− (or “−”) of comparator 531 can be coupled to gate G2 of transistor 523N (FIG. 5A). Input node 531+ (or “+”) of comparator 531 can coupled to voltage V2 (e.g., V2=0.5V).

The gates of transistors P4 through P7 and N4 through N6 can be selectively provided with (e.g., controlled by) signals Vo_BUF and Vo_BUF*, and clock signals CLK_IL and CLK_IL*. Clock signals CLK_IL is the same as signal CLK_IL at node 211 in FIG. 5A. Signal CLK_IL* in FIG. 6A can be an inverted version of clock signal CLK_IL.

Comparator 531 can generate signal Vo_CMP based on the comparison of voltages V2 (at node 531+) and a voltage at node 531− (from gate G2). As shown in FIG. 6A, comparator 531 can generate signals Vo_BUF at the output node of buffer 612 Vo_BUF* based on signal Vo_CMP. Comparator 531 can generate signals Vo_BUF* at the output node of inverter 613 Vo_BUF* based on signal Vo_BUF. Signals Vo_BUF and Vo_BUF* are inverted versions of each other.

Comparator 531 can be a self-biased comparator with power gating, such that the bias core of comparator 531 is enabled during only part of a period (e.g., only during a rising edge) of the signal at node 531− of comparator 531 (which is coupled to gate G2 of transistor 523N of FIG. 5A). Power gating allows comparator 531 to consume a relatively small amount of power. This can lead to overall power saving in clock generator 141 that includes comparator 531.

FIG. 6B shows comparator 532 of clock generator 141 of FIG. 5A, according to some embodiments described herein. As shown in FIG. 6B, comparator 532 in FIG. 6B includes similar or the same circuit elements (e.g., transistors) as comparator 531 of FIG. 6A. Differences between comparators 531 and 532 include the voltage and signals applied to respective input nodes 532+ (or “+”) and 532− (or “−”). As shown in FIG. 6B, input node 532− of comparator 532 can be coupled to voltage V2 (e.g., V2=0.5V), and input node 532+ can be coupled to gate G1 of transistor 523N (FIG. 5A).

Like comparator 531 of FIG. 6A, comparator 532 of FIG. 6B can be a self-biased comparator with power gating, such that the bias core of comparator 532 is enabled during only part of a period (e.g., only during a rising edge) of the signal at node 531− of comparator 531 (which is coupled to gate G2 of transistor 523N of FIG. 5A). Power gating allows comparator 532 to consume a relatively small amount of power. This can lead to overall power saving in clock generator 141 that includes comparator 532.

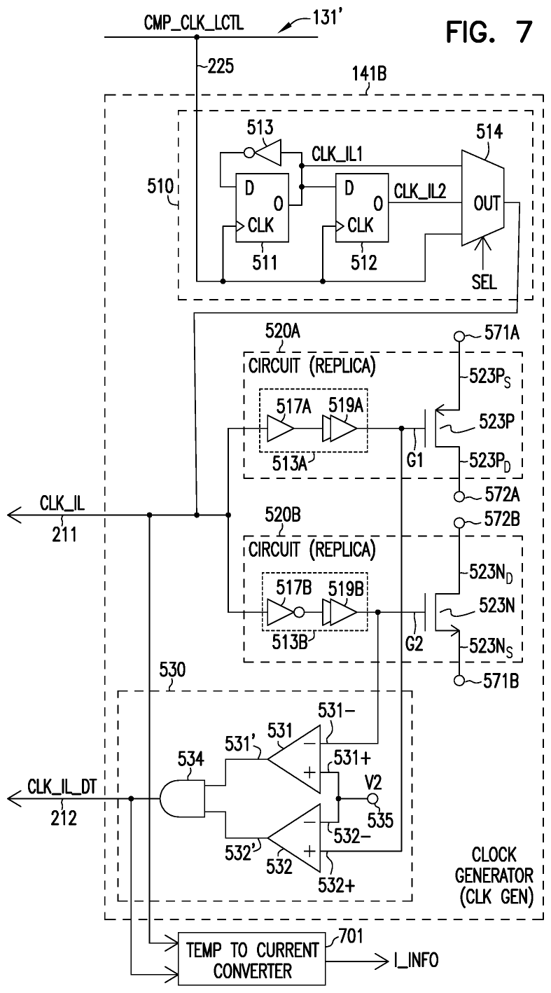

FIG. 7 shows clock generator 141B that can be variation of clock generator 141 of FIG. 5A, according to some embodiments described herein. As shown in FIG. 5A and FIG. 7, clock generator 141B in FIG. 7 can be the same as clock generator 141 of FIG. 5A except for the addition of temperature-to-current converter (e.g., conversion circuitry) 701 of clock generator 141B in FIG. 7. Clock generator 141B can operate to provide signals CLK_IL and CLK_IL_DT having waveforms and deadtime intervals (e.g., time intervals DT1 and DT2) similar to those shown in FIG. 3A. Temperature-to-current converter 701 can include input nodes coupled to respective nodes 211 and 212, and an output node to provide information (e.g., current information) I_INFO. Temperature-to-current converter 701 can operate to generate information I_INFO based on the temperature (e.g., operating temperature) of a respective power switching block 140 where clock generator 141B is located. Information I_INFO can include process-dependent current information and can be used (e.g., to generate or adjust control signals) in other circuits of voltage regulator 101 (FIG. 1) or load 103 (FIG. 1) or both.

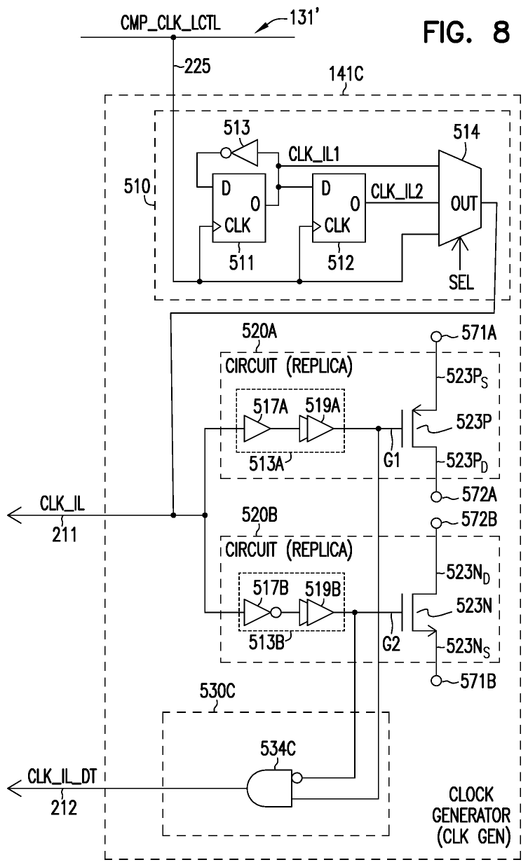

FIG. 8 shows clock generator 141C that can be a variation of clock generator 141 of FIG. 5A, according to some embodiments described herein. As shown in FIG. 5A and FIG. 8, clock generator 141C in FIG. 8 can be the same as clock generator 141 of FIG. 5A except for circuit 530C of clock generator 141C in FIG. 8. In FIG. 8, comparators 531 and 532 (shown in FIG. 5A) are omitted from circuit 530C. Gates G1 and G2 of transistors 523P and 523N, respectively, can be coupled to (e.g., directly coupled to) the input nodes (not labeled) of logic gate 534C. Logic gate 534C can be same as logic gate 534 of FIG. 5A, except that one of the input nodes (indicated by a circle symbol) of logic gate 534C can be an inverting input. Clock generator 141C can operate to provide signals CLK_IL and CLK_IL_DT having waveforms and deadtime intervals (e.g., time intervals DT1 and DT2) similar to those shown in FIG. 3A.

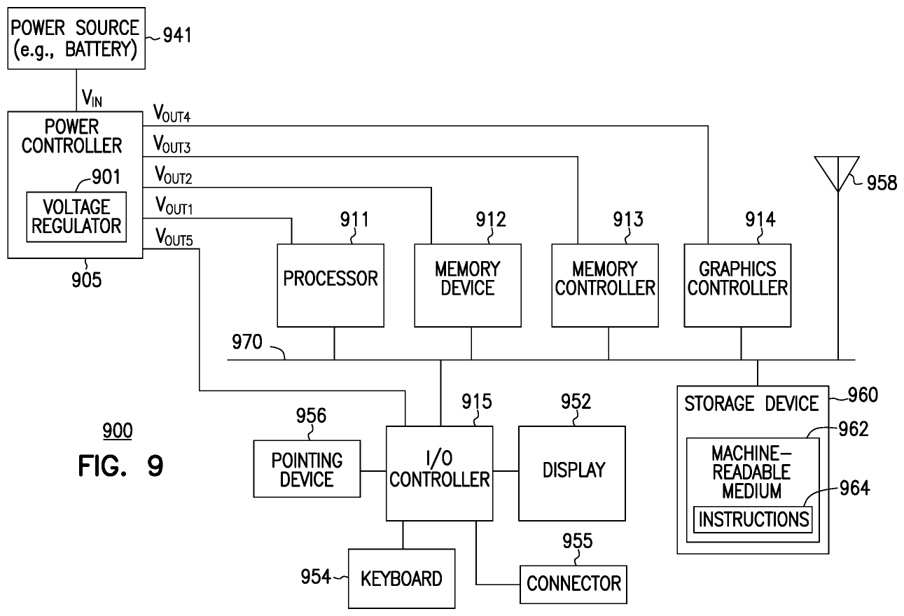

FIG. 9 shows an apparatus in the form of a system (e.g., electronic system) 900, according to some embodiments described herein. System 900 can be viewed as a machine. System (e.g., machine) System 900 can include or be included in a computer, a cellular phone, or other electronic systems. As shown in FIG. 9, system 900 can components (e.g., devices) that can include a power controller 905, a processor (e.g., hardware processor) 911, a memory device 912, a memory controller 913, a graphics controller 914, an input and output (I/O) controller 915, a display 952, a keyboard 954, a pointing device 956, at least one antenna 958, a storage device 960, and a bus 970. Bus 970 can include conductive lines (e.g., metal-based traces on a circuit board (e.g., printed circuit board, not shown) where the components of system 900 are located).

System 900 may be configured to perform one or more of the methods and/or operations described herein. At least one of the components of system 900 (e.g., at least one of power controller 905, processor 911, memory device 912, memory controller 913, graphics controller 914, and I/O controller 915) can include at least one of voltage converter 101 and load 103 of FIG. 1.

In FIG. 9, processor 911 can include a general-purpose processor or an application specific integrated circuit (ASIC). Processor 911 can include a CPU. Graphics controller 914 can include a GPU.

Memory device 912 can include a dynamic random-access memory (DRAM) device, a static random-access memory (SRAM) device, a flash memory device, phase change memory, or a combination of these memory devices, or other types of memory. FIG. 9 shows an example where memory device 912 is a stand-alone memory device separated from processor 911. In an alternative arrangement, memory device 912 and processor 911 can be located on the same IC die. In such an alternative arrangement, memory device 912 is an embedded memory in processor 911, such as embedded DRAM (eDRAM), embedded SRAM (eSRAM), embedded flash memory, or another type of embedded memory.

Storage device 960 can include drive unit (e.g., hard disk drive (HHD), solid-state drive (SSD), or another mass storage device). Storage device 960 can include a machine-readable medium 962 and processing circuitry. Machine-readable medium 962 can store one or more sets of data structures or instructions 964 (e.g., software) embodying or used by any one or more of the techniques or functions described herein. Instructions 964 may also reside, completely or at least partially, within power controller 905, processor 911, memory device 912, memory controller 913, graphics controller 914 during execution thereof by system (e.g., machine) 900.

In an example, one of (or any combination of) power controller 905, processor 911, memory device 912, memory controller 913, graphics controller 914, and storage device 960 may constitute machine-readable media. Non-limiting machine-readable medium examples may include solid-state memories and optical and magnetic media. Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

FIG. 9 shows machine-readable medium 962 as a single medium as an example. However, the term “machine-readable medium” may include a single medium or multiple media (e.g., a centralized or distributed database, and/or associated caches and servers) configured to store instructions 964. Further, the term “machine-readable medium” may include any medium that is capable of storing, encoding, or carrying instructions for execution by system 900 and that causes system 900 to perform any one or more of the techniques of the present disclosure, or that is capable of storing, encoding or carrying data structures used by or associated with such instructions. In some examples, machine-readable media may include non-transitory machine-readable media. In some examples, machine-readable media may include machine-readable media that is not a transitory propagating signal.

Display 952 can include a liquid crystal display (LCD), a touchscreen (e.g., capacitive or resistive touchscreen), or another type of display. Pointing device 956 can include a mouse, a stylus, or another type of pointing device. In some arrangements, system 900 does not have to include a display. Thus, display 952 can be omitted from system 900.

Antenna 958 can include one or more directional or omnidirectional antennas, including, for example, dipole antennas, monopole antennas, patch antennas, loop antennas, microstrip antennas, or other types of antennas suitable for transmission of radio frequency (RF) signals. In some structures, system 900 does not have to include an antenna. Thus, in such structures, antenna 958 can be omitted from system 900.

I/O controller 915 can include a communication module for wired or wireless communication (e.g., communication through one or more antennas 958). Such wireless communication may include communication in accordance with WiFi communication technique, Long Term Evolution Advanced (LTE-A) communication technique, or other communication techniques.

I/O controller 915 can also include a module to allow system 900 to communicate with other devices or systems in accordance with to one or more of the following standards or specifications (e.g., I/O standards or specifications), including Universal Serial Bus (USB), DisplayPort (DP), High-Definition Multimedia Interface (HDMI), Thunderbolt, Peripheral Component Interconnect Express (PCIe), Ethernet, and other specifications.

Connector 955 can include terminals (e.g., pins) to allow system 900 to be coupled to an external device (or system). This may allow system 900 to communicate (e.g., exchange information) with such a device (or system) through connector 955. Connector 955 and at least a portion of bus 970 can include conductive lines that conform with at least one of USB, DP, HDMI, Thunderbolt, PCIe, Ethernet, and other specifications.

Power controller 905 can be configured to receive power (e.g., supply voltage) from a power source 941 that can provide a voltage V_{IN}, which can correspond to voltage V_{IN} described above with reference to FIG. 1 through FIG. 8. Power controller 905 can provide voltages V_{OUT1}, V_{OUT2}, V_{OUT3}, V_{OUT4}, and V_{OUT5} based on voltage V_{IN}. Each of voltages V_{OUT1}, V_{OUT2}, V_{OUT3}, V_{OUT4}, and V_{OUT5} can correspond to voltage V_{OUT} described about with reference to FIG. 1 through FIG. 8. Voltages V_{OUT1}, V_{OUT2}, V_{OUT3}, V_{OUT4}, and V_{OUT5} can be provided to processor 911, memory device 912, memory controller 913, graphics controller 914, and I/O controller 915, respectively.

Power controller 905 can include a voltage regulator 901 to control the value at least one of voltages V_{OUT1}, V_{OUT2}, V_{OUT3}, V_{OUT4}, and V_{OUT5} in ways similar to, or the same as, controlling of voltage V_{OUT} described above with reference to FIG. 1 or FIG. 8.

FIG. 9 shows the components of system 900 arranged separately from each other as an example. For example, each of power controller 905, processor 911, memory device 912, memory controller 913, graphics controller 914, and I/O controller 915 can be located on a separate IC die (e.g., a semiconductor die or an IC chip). In some arrangements, two or more components (e.g., power controller 905, processor 911, memory device 912, graphics controller 914, and I/O controller 915) of system 900 can be located on the same die (e.g., same IC chip), forming a system-on-chip.

The illustrations of the apparatuses (e.g., voltage regulator 101 and system 900) and methods (e.g., method of operating voltage regulator 101 and system 900) described above are intended to provide a general understanding of the structure of different embodiments and are not intended to provide a complete description of all the elements and features of an apparatus that might make use of the structures described herein. An apparatus herein refers to, for example, either a device (e.g., voltage regulator 101) or a system (e.g., system 900 that can include voltage regulator 101, load 103, or both).

Any of the components described above with reference to FIG. 1 through FIG. 9 can be implemented in a number of ways, including simulation via software. Thus, apparatuses (e.g., voltage regulator 101 or part of voltage regulator 101) may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The apparatuses and methods described above can include or be included in high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

In the detailed description and the claims, the terms “first,” “second,” and “third,” etc. are used merely as labels, and are not intended to impose numerical requirements on their objects.

In the detailed description and the claims, the term “adjacent” generally refers to a position of a thing being next to (e.g., either immediately next to or close to with one or more things between them) or adjoining another thing (e.g., abutting it or contacting it (e.g., directly coupled to) it).

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description describes implementations of the subject matter that can include one or more features, alone or in combination as illustrated below by way of examples.

Example 1 is an apparatus: a clock node included in a voltage regulator to receive an input clock signal, a first power switching block included in the voltage regulator, the first power switching block including a first clock generator and first switched capacitor circuitry, the first clock generator including a clock input node to receive the input clock signal, and clock output nodes to provide first clock signals based on the input clock signal, the first switched capacitor circuitry including input nodes to receive first control signals generated based on the first clock signals, and a second power switching block included in the voltage regulator, the second power switching block, including a second clock generator and second switched capacitor circuitry, the second clock generator including a clock input node to receive the input clock signal, and clock output nodes to provide second clock signals based on the input clock signal, the second switched capacitor circuitry including input nodes to receive second control signals generated based on the second clock signals.

In Example 2, the subject matter of any of Example 1 includes subject matter wherein the voltage regulator includes a conductive line coupled to clock node and the first and second power switching blocks, a third power switching block coupled to the conductive line, the third power switching block including a third clock generator and third switched capacitor circuitry, the third clock generator including a clock input node to receive the input clock signal, and clock output nodes to provide third clock signals based on the input clock signal, the third switched capacitor circuitry including input nodes to receive third control signals generated based on the third clock signals, a fourth power switching block coupled to the conductive line, the fourth power switching block including a fourth clock generator and fourth switched capacitor circuitry, the fourth clock generator including a clock input node to receive the input clock signal, and clock output nodes to provide fourth clock signals based on the input clock signal, the fourth switched capacitor circuitry including input nodes to receive fourth control signals generated based on the fourth clock signals, and wherein the first and second power switching blocks are located on a first side of the conductive line, and third and fourth power switching blocks are located on a second side of the conductive line opposite from the first side.

In Example 3, the subject matter of Example 2 includes subject matter wherein the voltage regulator includes buffer circuitry, the buffer circuitry including an output node coupled to the clock node, wherein the conductive line is part of a clock path coupled to each of the first, second, third, and fourth clock generators, and an area between the first side of the conductive line and each of the first and second power switching blocks and an area between the second side of the conductive line and each of the third and fourth power switching blocks are without an additional clock path from the buffer circuitry to the first, second, third, and fourth clock generators.

In Example 4, the subject matter of Example 1 includes buffer circuitry including an input node to receive the input clock, and an output node to provide an additional input clock signal, a third power switching block coupled to the output node of the buffer circuit, the third power switching block including a third clock generator and third switched capacitor circuitry, the third clock generator including a clock input node to receive the additional input clock signal, and clock output nodes to provide third clock signals based on the additional input clock signal, the third switched capacitor circuitry including input nodes to receive third control signals generated based on the third clock signals, and a fourth power switching block coupled to the output node of the buffer circuitry, the fourth power switching block including a fourth clock generator and fourth switched capacitor circuitry, the fourth clock generator including a clock input node to receive the additional input clock signal, and clock output nodes to provide fourth clock signals based on the additional input clock signal, the fourth switched capacitor circuitry including input nodes to receive fourth control signals generated based on the fourth clock signals.

In Example 5, the subject matter of Example 1 includes subject matter wherein the voltage regulator includes a voltage input node, a voltage output node, wherein each of the first and second switched capacitor circuitries includes an input node coupled to the voltage input node, and an output node coupled to the voltage output node, a comparator including a first input node coupled to a voltage node, a second input to receive a voltage based on an output voltage at the voltage output node, and buffer circuitry including an input node coupled to an output node of the comparator, and an output node coupled to the clock node.

In Example 6, the subject matter of Example 5 includes additional buffer circuitry including an input node coupled to the clock node, and additional power switching blocks, each of the additional power switching blocks including an additional clock generator and additional switched capacitor circuitry, additional clock generator including an clock input node to receive an additional input clock signal from an output node of the additional buffer circuitry, and clock output nodes to provide third clock signals based on the additional input clock signal, the switched capacitor circuitry including input nodes to receive additional control signals generated based on the third clock signals.

In Example 7, the subject matter of Example 5 includes a processor, and a power controller coupled to the processor, wherein the power controller includes the first power switching block, and the second power switching block.

In Example 8, the subject matter of Example 1 includes subject matter wherein each of the first and second power switching includes a capacitor and first circuits to a plate of the capacitor, each of the first and second clock generators includes a second circuit and a third circuit coupled to the second circuit, a structure of the second circuit is based on a structure of one of the first circuits, and a structure of the third circuit is based on a structure of one of the first circuits.

In Example 9, the subject matter of Example 1 includes subject matter wherein each of the first and second power switching includes a capacitor and first circuits to a plate of the capacitor, and each of the first and second clock generators includes a second circuit and a third circuit coupled to the second circuit, the second circuit is replica of one of the first circuits, and the third circuit is replica of one of the first circuits.

In Example 10, the subject matter of any of Examples 1, 8, and 9 includes subject matter wherein each of the first circuits includes a driver and a transistor coupled to first driver.

In Example 11, the subject matter of Example 10 includes subject matter wherein the second circuit includes a first transistor, and the third circuit includes a second transistor, wherein the first and second transistors have different transistor types.

In Example 12, the subject matter of Example 8 includes subject matter wherein each of the first and second power switching includes a capacitor and first circuits to a plate of the capacitor, and each of the first and second clock generators includes a second circuit and a third circuit coupled to the second circuit, the second circuit includes a second driver and second transistor coupled to the second driver, wherein the second transistor has a size greater than a size of a transistor of one of the first circuits, and the third circuit includes a third driver and third transistor coupled to third driver, wherein the third transistor has a size greater than a size of a transistor of one of the first circuits.

In Example 13, the subject matter of Example 12 includes subject matter wherein the second transistor includes a p-type transistor, and the third transistor includes an n-type transistor In Example 14, the subject matter of Example 9 includes subject matter wherein the size of the second transistor is two times the size of the transistor of one of the first circuits, and the size of the third transistor is two times the size of the transistor of one of the first circuits.

In Example 15, the subject matter of any of Examples 8 and 9 includes subject matter wherein each of the first and second clock generators includes a first circuit including an input node coupled to the clock node, a second circuit including a first driver and a first transistor, the first driver including an input node coupled to the clock output node, and an output node coupled to a gate of the first transistor, a third circuit including a second driver and a second transistor, the second driver including an input node coupled to the clock output node, and an output node coupled to a gate of the second transistor, a first comparator including a first input node coupled to a voltage node and a second input node coupled to the gate of the first transistor, a second comparator including a first input node coupled to the voltage node and a second input node coupled to the gate of the second transistor, and a logic gate including a first input node coupled to an output node of the first comparator, a second input node coupled to an output node of the second comparator.

In Example 16, the subject matter of any of Examples 2 and 3 includes subject matter wherein the conductive line is at least one millimeter.

Example 17 is an apparatus comprising: a clock node, a voltage input node and a voltage output node, a first power switching block including a first clock generator coupled to the clock node and first switched capacitor circuitry including a first capacitor and first circuits, each of the first circuits including a first node coupled to a plate of the first capacitor, and a second node coupled to one of the voltage input node and the voltage output node, and a second power switching block including a second clock generator coupled to the clock node and second switched capacitor circuitry including a second capacitor and second circuits, each of the second circuits including a first node coupled to a plate of the second capacitor and a second node coupled to one of the voltage input node and the voltage output node, wherein each of the first and second clock generators includes a third circuit and a fourth circuit coupled to the third circuit, a structure of the third circuit is based on a structure of a first selected circuit among the first circuits and the second circuits, and a structure of the fourth circuit is based on a structure of a second selected circuit among the first circuits and second circuits.

In Example 18, the subject matter of Example 17 includes subject matter wherein the first selected circuit includes a first transistor, the second selected circuit includes a second transistor, the third circuit includes a third transistor, wherein the third transistor is a replica of the first transistor, and the fourth circuit includes a fourth transistor, wherein the fourth transistor is a replica of the second transistor.

In Example 19, the subject matter of Example 18 includes subject matter wherein the third transistor includes a source and a drain coupled to a same first node, and the fourth transistor includes a source and a drain coupled to a same second node.

In Example 21, the subject matter of Example 17 includes subject matter where the first selected circuit includes a first transistor, the second selected circuit includes a second transistor, the third circuit includes a third transistor, wherein a size of the third transistor is greater than a size of the first transistor, and the fourth circuit includes a fourth transistor, wherein a size of the fourth transistor is greater than a size of the second transistor.

In Example 22, the subject matter of Example 17 includes subject matter wherein each of the first and second clock generators includes a flip-flop including a clock input coupled to the clock node, and a multiplexer including a first input coupled to the clock node and second input coupled to an output node of the flip-flop, and an output node coupled to an output node of a respective clock generator of the first and second clock generators.

In Example 23, the subject matter of Example 17 includes subject matter wherein each of the first and second clock generators includes a first additional circuit and a second additional circuit, and wherein the first additional circuit includes a clock input node coupled to the clock node to receive a first clock signal, and a clock output node to provide a second clock signal, the third circuit includes a first driver and a first transistor, the first driver including an input node coupled to the clock output node, and an output node coupled to a gate of the first transistor, the fourth circuit includes a second driver and a second transistor, the second driver including an input node coupled to the clock output node, and an output node coupled to a gate of the second transistor, and the second additional circuit includes a first input node coupled to the gate of the first transistor, a second input node coupled to the gate of the second transistor, and an output node to provide a third clock signal.

In Example 24, the subject matter of Example 23 includes subject matter wherein the second additional circuit includes a first comparator including a first input node coupled to a voltage node and a second input node coupled to the gate of the first transistor, a second comparator including a first input node coupled to the voltage node and a second input node coupled to the gate of the second transistor, and a logic gate including a first input node coupled to an output node of the first comparator, a second input node coupled to an output node of the second comparator, and an output node coupled to the output node of the second additional circuit.

In Example 25, the subject matter of Example 23 includes a temperature-to-current converter coupled to the clock output node and the output node of the second additional circuit.

In Example 26, the subject matter of Example 23 includes subject matter wherein the second additional circuit includes a logic gate, wherein the logic gate includes a first input node coupled to the gate of the first transistor, a second input node coupled the gate of the second transistor, and an output node coupled to the output node of the second additional circuit.

In Example 27, the subject matter of Example 17 includes subject matter wherein a number of circuit elements of the third circuit is a same as a number of circuit elements the first circuit, and a number of circuit elements of the fourth circuit is a same as a number of circuit elements of the second circuit.

In Example 28, the subject matter of Example 17 includes subject matter wherein the apparatus comprises a semiconductor die, and the clock node, the voltage input node, a voltage output node, and the first and second power switching blocks are located on the semiconductor die.

In Example 29, the subject matter of any of Examples 17-28 includes subject matter wherein apparatus comprises a system-on-chip (SoC).

In Example 30, the subject matter of any of Examples 17-28 includes a connector and an integrated circuit (IC) chip coupled to the connector, the IC chip including the first power switching block, and the second power switching block, wherein the connector conforms with at least one of Universal Serial Bus (USB), High-Definition Multimedia Interface (HDMI), Thunderbolt, Peripheral Component Interconnect Express (PCIe), and Ethernet specifications.

Example 31 is method comprising: generating an input clock signal based on a clock signal from an output node of a comparator of a voltage regulator, providing the input clock signal to a first clock generator of a first power switching block of the voltage regulator, providing the input clock signal to a second clock generator of a second power switching block of the voltage regulator, generating, at the first clock generator, a first clock signal based on the input clock signal, generating, at the first clock generator, a second clock signal based on the first clock signal, wherein the second clock signal at the first clock generator is generated such that a time interval between two closest edges of the first and second clock signals is based on a first voltage at a gate of a first transistor in the first clock generator and a second voltage at a gate of a second transistor in the first clock generator, generating, at the second clock generator, a third clock signal based on the input clock signal, generating, at the second clock generator, a fourth clock signal based on the third clock signal, wherein the fourth clock signal is generated such that a time interval between two closest edges of the third and fourth clock signals at the second clock generator is based on a first voltage at a gate of a first transistor in the second clock generator and a second voltage at a gate of a second transistor in the second clock generator, providing first control signals to switched capacitor circuitry of the first power switching block, wherein a time interval between edges of the first control signals are based on the time interval between two closest edges of the first and second clock signals, and providing the second control signals to switched capacitor circuitry of the second power switching block, wherein a time interval between edges of the second control signals are based on the time interval between two closest edges of the third and fourth clock signals.

In Example 32, the subject matter of Example 31 includes subject matter wherein the input clock signal has a frequency greater than a frequency of each of the first and second clock signals.

In Example 33, the subject matter of Example 31 includes, providing the input clock signal to an input node of buffer circuitry, generating, at the buffer circuitry, an additional input clock signal at an output node of the buffer circuitry, providing the additional input clock signal to a clock generator of each power switching block of additional power switching blocks of the voltage regulator, generating, at the clock generator of each power switching block of the additional power switching blocks, a fifth clock signal based on the additional input clock signal at the third clock generator and a sixth clock signal based on the fifth clock signal, and providing additional control signals to switched capacitor circuitries of the additional power switching blocks, wherein a time interval between edges of the additional control signals at a switched capacitor circuitry of the additional power switching blocks are based on the time interval between two closest edges of the fifth and sixth clock signals at a respective clock generator of the additional power switching blocks.

Example 34 is at least one machine-readable medium including instructions that, when executed by processing circuitry, cause the processing circuitry to perform operations to implement any of Examples 1-33.

Example 35 is an apparatus comprising means to implement any of Examples 1-33.

Example 36 is a system to implement any of Examples 1-33.

Example 37 is a method to implement any of Examples 1-33.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description

The Abstract is provided to allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus comprising:
a clock node included in a voltage regulator to receive an input clock signal;
a first power switching block included in the voltage regulator, the first power switching block including a first clock generator and first switched capacitor circuitry, the first clock generator including a clock input node to receive the input clock signal, and clock output nodes to provide first clock signals based on the input clock signal, the first switched capacitor circuitry including input nodes to receive first control signals generated based on the first clock signals; and
a second power switching block included in the voltage regulator, the second power switching block, including a second clock generator and second switched capacitor circuitry, the second clock generator including a clock input node to receive the input clock signal, and clock output nodes to provide second clock signals based on the input clock signal, the second switched capacitor circuitry including input nodes to receive second control signals generated based on the second clock signals.

2. The apparatus of claim 1, wherein the voltage regulator includes:
a conductive line coupled to clock node and the first and second power switching blocks;
a third power switching block coupled to the conductive line, the third power switching block including a third clock generator and third switched capacitor circuitry, the third clock generator including a clock input node to receive the input clock signal, and clock output nodes to provide third clock signals based on the input clock signal, the third switched capacitor circuitry including input nodes to receive third control signals generated based on the third clock signals;
a fourth power switching block coupled to the conductive line, the fourth power switching block including a fourth clock generator and fourth switched capacitor circuitry, the fourth clock generator including a clock input node to receive the input clock signal, and clock output nodes to provide fourth clock signals based on the input clock signal, the fourth switched capacitor circuitry including input nodes to receive fourth control signals generated based on the fourth clock signals; and
wherein the first and second power switching blocks are located on a first side of the conductive line, and third and fourth power switching blocks are located on a second side of the conductive line opposite from the first side.

3. The apparatus of claim 2, the voltage regulator includes buffer circuitry, the buffer circuitry including an output node coupled to the clock node, wherein:
the conductive line is part of a clock path coupled to each of the first, second, third, and fourth clock generators; and
an area between the first side of the conductive line and each of the first and second power switching blocks and an area between the second side of the conductive line and each of the third and fourth power switching blocks are without an additional clock path from the buffer circuitry to the first, second, third, and fourth clock generators.

4. The apparatus of claim 1, further comprising:
buffer circuitry including an input node to receive the input clock, and an output node to provide an additional input clock signal;
a third power switching block coupled to the output node of the buffer circuit, the third power switching block including a third clock generator and third switched capacitor circuitry, the third clock generator including a clock input node to receive the additional input clock signal, and clock output nodes to provide third clock signals based on the additional input clock signal, the third switched capacitor circuitry including input nodes to receive third control signals generated based on the third clock signals; and
a fourth power switching block coupled to the output node of the buffer circuitry, the fourth power switching block including a fourth clock generator and fourth switched capacitor circuitry, the fourth clock generator including a clock input node to receive the additional input clock signal, and clock output nodes to provide fourth clock signals based on the additional input clock signal, the fourth switched capacitor circuitry including input nodes to receive fourth control signals generated based on the fourth clock signals.

5. The apparatus of claim 1, wherein the voltage regulator includes:
a voltage input node;
a voltage output node, wherein each of the first and second switched capacitor circuitries includes an input node coupled to the voltage input node, and an output node coupled to the voltage output node;
a comparator including a first input node coupled to a voltage node, a second input to receive a voltage based on an output voltage at the voltage output node; and
buffer circuitry including an input node coupled to an output node of the comparator, and an output node coupled to the clock node.

6. The apparatus of claim 5, further comprising:
additional buffer circuitry including an input node coupled to the clock node; and
additional power switching blocks, each of the additional power switching blocks including an additional clock generator and additional switched capacitor circuitry, additional clock generator including an clock input node to receive an additional input clock signal from an output node of the additional buffer circuitry, and clock output nodes to provide third clock signals based on the additional input clock signal, the switched capacitor circuitry including input nodes to receive additional control signals generated based on the third clock signals.

7. The apparatus of claim 1, further comprising:
a processor; and
a power controller coupled to the processor, wherein the power controller includes the first power switching block, and the second power switching block.

8. An apparatus comprising:
a clock node;
a voltage input node and a voltage output node;
a first power switching block including a first clock generator coupled to the clock node and first switched capacitor circuitry including a first capacitor and first circuits, each of the first circuits including a first node coupled to a plate of the first capacitor, and a second node coupled to one of the voltage input node and the voltage output node; and
a second power switching block including a second clock generator coupled to the clock node and second switched capacitor circuitry including a second capacitor and second circuits, each of the second circuits including a first node coupled to a plate of the second capacitor and a second node coupled to one of the voltage input node and the voltage output node, wherein:
each of the first and second clock generators includes a third circuit and a fourth circuit coupled to the third circuit;
a structure of the third circuit is based on a structure of a first selected circuit among the first circuits and the second circuits; and
a structure of the fourth circuit is based on a structure of a second selected circuit among the first circuits and second circuits.

9. The apparatus of claim 8, wherein:
the first selected circuit includes a first transistor;
the second selected circuit includes a second transistor;
the third circuit includes a third transistor, wherein the third transistor is a replica of the first transistor; and
the fourth circuit includes a fourth transistor, wherein the fourth transistor is a replica of the second transistor.

10. The apparatus of claim 9, wherein:
the third transistor includes a source and a drain coupled to a same first node; and
the fourth transistor includes a source and a drain coupled to a same second node.

11. The apparatus of claim 9, wherein:
the first selected circuit includes a first driver coupled to the first transistor;
the second selected circuit includes a second driver coupled to the second transistor;
the third circuit includes a third driver coupled to the third transistor, wherein the third driver is a replica of the first driver; and
the fourth circuit includes a fourth driver coupled to the fourth transistor, wherein the fourth driver is a replica of the second driver.

12. The apparatus of claim 8, wherein:
the first selected circuit includes a first transistor;
the second selected circuit includes a second transistor;
the third circuit includes a third transistor, wherein a size of the third transistor is greater than a size of the first transistor; and
the fourth circuit includes a fourth transistor, wherein a size of the fourth transistor is greater than a size of the second transistor.

13. The apparatus of claim 8, wherein each of the first and second clock generators includes:
a flip-flop including a clock input coupled to the clock node; and
a multiplexer including a first input coupled to the clock node and second input coupled to an output node of the flip-flop, and an output node coupled to an output node of a respective clock generator of the first and second clock generators.

14. The apparatus of claim 8, wherein each of the first and second clock generators includes a first additional circuit and a second additional circuit, and wherein:
the first additional circuit includes a clock input node coupled to the clock node to receive a first clock signal, and a clock output node to provide a second clock signal;
the third circuit includes a first driver and a first transistor, the first driver including an input node coupled to the clock output node, and an output node coupled to a gate of the first transistor;
the fourth circuit includes a second driver and a second transistor, the second driver including an input node coupled to the clock output node, and an output node coupled to a gate of the second transistor; and
the second additional circuit includes a first input node coupled to the gate of the first transistor, a second input node coupled to the gate of the second transistor, and an output node to provide a third clock signal.

15. The apparatus of claim 14, wherein the second additional circuit includes:
a first comparator including a first input node coupled to a voltage node and a second input node coupled to the gate of the first transistor;
a second comparator including a first input node coupled to the voltage node and a second input node coupled to the gate of the second transistor; and
a logic gate including a first input node coupled to an output node of the first comparator, a second input node coupled to an output node of the second comparator, and an output node coupled to the output node of the second additional circuit.

16. The apparatus of claim 14, further comprising a temperature-to-current converter coupled to the clock output node and the output node of the second additional circuit.

17. The apparatus of claim 8, further comprising a connector and an integrated circuit (IC) chip coupled to the connector, the IC chip including the first power switching block, and the second power switching block, wherein the connector conforms with at least one of Universal Serial Bus (USB), High-Definition Multimedia Interface (HDMI), Thunderbolt, Peripheral Component Interconnect Express (PCIe), and Ethernet specifications.

18. A method comprising:
generating an input clock signal based on a clock signal from an output node of a comparator of a voltage regulator;
providing the input clock signal to a first clock generator of a first power switching block of the voltage regulator;
providing the input clock signal to a second clock generator of a second power switching block of the voltage regulator;
generating, at the first clock generator, a first clock signal based on the input clock signal;
generating, at the first clock generator, a second clock signal based on the first clock signal, wherein the second clock signal at the first clock generator is generated such that a time interval between two closest edges of the first and second clock signals is based on a first voltage at a gate of a first transistor in the first clock generator and a second voltage at a gate of a second transistor in the first clock generator;
generating, at the second clock generator, a third clock signal based on the input clock signal;
generating, at the second clock generator, a fourth clock signal based on the third clock signal, wherein the fourth clock signal is generated such that a time interval between two closest edges of the third and fourth clock signals at the second clock generator is based on a first voltage at a gate of a first transistor in the second clock generator and a second voltage at a gate of a second transistor in the second clock generator;
providing first control signals to switched capacitor circuitry of the first power switching block, wherein a time interval between edges of the first control signals are based on the time interval between two closest edges of the first and second clock signals; and
providing the second control signals to switched capacitor circuitry of the second power switching block, wherein a time interval between edges of the second control signals are based on the time interval between two closest edges of the third and fourth clock signals.

19. The method of claim 18, wherein the input clock signal has a frequency greater than a frequency of each of the first and second clock signals.

20. The method of claim 18, further comprising:
providing the input clock signal to an input node of buffer circuitry;
generating, at the buffer circuitry, an additional input clock signal at an output node of the buffer circuitry;
providing the additional input clock signal to a clock generator of each power switching block of additional power switching blocks of the voltage regulator;
generating, at the clock generator of each power switching block of the additional power switching blocks, a fifth clock signal based on the additional input clock signal at the third clock generator and a sixth clock signal based on the fifth clock signal; and
providing additional control signals to switched capacitor circuitries of the additional power switching blocks, wherein a time interval between edges of the additional control signals at a switched capacitor circuitry of the additional power switching blocks are based on the time interval between two closest edges of the fifth and sixth clock signals at a respective clock generator of the additional power switching blocks.
